(19) United States
(12) Patent Application Publication
(10) Pub. No.: US 2026/0060097 A1
(43) Pub. Date: Feb. 26, 2026

(54) ALL-GLASS STACKED PACKAGING STRUCTURE AND PREPARATION METHOD THEREOF

(71) Applicant: GUANGDONG FOZHIXIN MICROELECTRONICS CO., LTD., Foshan City (CN)

(72) Inventors: Chuman HO, Foshan (CN); Bin YANG, Foshan (CN); Xiangang HUA, Foshan (CN)

(21) Appl. No.: 18/842,603

(22) PCT Filed: Aug. 25, 2023
(86) PCT No.: PCT/CN2023/114989

§ 371 Date: Aug. 29, 2024

(30) Foreign Application Priority Data
Aug. 1, 2023 (CN) 202310959645.7

(51) Int. Cl. H01L 21/48; H01L 23/00; H01L 23/15; H01L 23/498

(52) U.S. Cl. CPC H01L 21/4846; H01L 23/15; H01L 23/49816; H01L 23/49822; H01L 24/16; H01L 2224/16225

(57) ABSTRACT

The method of preparing an all-glass stacked packaging structure includes the following steps: S1: providing an embedded chip fan-out packaging structure provided with a glass substrate and a glass metallized circuit structure provided with a glass substrate, and butt-joining and securing by welding a metal bump of the embedded chip fan-out packaging structure to a second redistribution layer of the glass metallized circuit structure; and S2: filling a gap between the embedded chip fan-out packaging structure and the glass metallized circuit structure with an inorganic silicate or an alkali metal-free silicon compound, and carrying out sintering to obtain the all-glass stacked packaging structure.

### TECHNICAL FIELD

This application claims priority to Chinese Patent Application No. 202310959645.7 filed on Aug. 1, 2023, the disclosure of which is incorporated herein by reference in its entirety. The present application relates to the field of integrated circuit packaging technologies, for example, to an all-glass stacked packaging structure and a preparation method thereof.

### BACKGROUND

In the related art, for a semiconductor stacked member, multiple semiconductor chips are generally stacked together via a bonding material, and the stacked semiconductor chips are then packaged by using a molding material or an underfill material to form a semiconductor stacked packaging structure.

A three-dimensional fan-out packaging structure and a preparation method thereof are disclosed in the related art. In the aforementioned method, a groove is dug in a carrier, a metal wiring layer is prepared at the groove and the periphery of the groove, a core particle is then pasted, a part of the pins of the core particle are led out to the front surface of the carrier through the metal wiring layer, the plastic packaging is carried out, a conductive column is prepared at a plastic packaging layer, and the part of pins are led out. Then a first redistribution layer and a first dielectric layer are prepared on the plastic packaging layer to complete front packaging. The back surface of the carrier is thinned to the metal wiring layer, the other part of the pins of the core particle are exposed, and then a second redistribution layer and a second dielectric layer are prepared to complete the preparation of a double-sided fan-out packaging unit. The fan-out packaging units are stacked according to needs and then connected via solder balls to obtain the three-dimensional fan-out packaging structure.

In the related art, the fan-out package units are stacked and then connected via solder balls, and the fan-out package units, when subjected to external forces, are prone to be misaligned with each other, resulting in poor connection stability between the fan-out package units.

### SUMMARY

The present application provides a method of preparing an all-glass stacked packaging structure, which can effectively improve the connection stability between an embedded chip fan-out packaging structure and a glass metallized circuit structure.

In an aspect, an embodiment of the present application provides a method of preparing an all-glass stacked packaging structure. The method of preparing an all-glass stacked packaging structure includes steps S1 and S2.

In S1, an embedded chip fan-out packaging structure provided with a glass substrate and a glass metallized circuit structure provided with a glass substrate are provided, and a metal bump of the embedded chip fan-out packaging structure is butt-joined and secured by welding to a second redistribution layer of the glass metallized circuit structure.

In S2, the gap between the embedded chip fan-out packaging structure and the glass metallized circuit structure is filled with a connecting material, and sintering is carried out on the connecting material to obtain the all-glass stacked packaging structure, where the connecting material is an inorganic silicate or an alkali metal-free compound.

In the present application, after an embedded chip fan-out packaging structure is butt-joined to a glass metallized circuit structure, a metal bump of the embedded chip fan-out packaging structure is secured by welding to a redistribution layer of the glass metallized circuit structure, the gap between the embedded chip fan-out packaging structure and the glass metallized circuit structure is then filled with a connecting material, and sintering is carried out on the connecting material to enable the embedded chip fan-out packaging structure to be fixedly connected to the glass substrate of the glass metallized circuit structure by sintering the connecting material. By carrying out securing by sintering the connecting material, the stability of the electrical connection between the embedded chip fan-out packaging structure and the glass metallized circuit structure can be further improved, thereby preparing an all-glass stacked packaging structure with a more stable structure.

In the present application, with the utilization of the characteristics of glass such as good rigidity, high flatness and excellent dielectric properties, a chip is mounted in an embedded manner by using a glass substrate, and a circuit structure is fabricated by using a glass substrate, which has high application value and great application prospects in the fields of high-density substrates and radio frequency.

In an embodiment, in step S2, when the connecting material is an inorganic silicate, the sintering is carried out at 160-300° C. for 0.5-4 h; when the connecting material is an alkali metal-free compound, the sintering is carried out at 100-200° C. for 0.5-2 h.

The inorganic silicate is Na₂O·nSiO₂, wherein n=0.1-5, and the alkali metal-free compound is silicone, resin or PI.

The common solid products of Na₂O·nSiO₂ include \textcircled{1} chunk solid, \textcircled{2} powder solid, \textcircled{3} soluble sodium silicate, \textcircled{4} sodium metasilicate, \textcircled{5} sodium metasilicate pentahydrate, and \textcircled{6} sodium orthosilicate.

In an embodiment, as a first scheme of the method of preparing an all-glass stacked packaging structure, in step S1, a method of preparing the embedded chip fan-out packaging structure includes steps S10 to S50.

In S10, a first glass substrate is provided, and a number of embedded grooves with a design size larger than the size of a chip are opened on the first glass substrate.

In S20, a first surface of the first glass substrate is attached onto a temporary adhesive film, and the chip is attached into an embedded groove of the embedded grooves.

In S30, a dielectric layer is prepared on each of the first surface of the first glass substrate and a second surface of the first glass substrate, and the dielectric layer is processed to expose an I/O port of the chip to obtain a chip package.

In S40, hole opening is carried out on the chip package to form a number of through holes penetrating through the chip package.

In S50, the I/O port of the chip is electrically led via a through hole of the through holes out of both surfaces of the chip package synchronously to obtain the embedded chip fan-out packaging structure.

In an embodiment, in step S20, the I/O port of the chip protrudes out of a surface of the chip, and after the chip is attached into the embedded groove with the front surface of the chip facing upwards, step S30 specifically includes steps S30a to S30d.

In S30a, a first dielectric layer is prepared on the second surface of the first glass substrate.

In S30b, the first dielectric layer is thinned by grinding to expose the I/O port of the chip.

In S30c, the temporary adhesive film is removed.

In S30d, a second dielectric layer is prepared on the first surface of the first glass substrate to obtain the chip package.

In an embodiment, in step S20, the I/O port of the chip is flush with a surface of the chip, and after the chip is attached into the embedded groove with the front surface of the chip facing upwards, step S30 specifically includes steps S30a to S30d.

In S30a, a first dielectric layer is prepared on the second surface of the first glass substrate.

In S30b, laser drilling is carried out on the first dielectric layer to expose the I/O port of the chip.

In S30c, the temporary adhesive film is removed.

In S30d, a second dielectric layer is prepared on the first surface of the first glass substrate to obtain the chip package.

In an embodiment, in step S20, the I/O port of the chip is flush with a surface of the chip, and after when the chip is attached into the embedded groove with the front surface of the chip facing downwards, step S30 specifically includes steps S30a to S30d.

In S30a, a first dielectric layer is prepared on the second surface of the first glass substrate.

In S30b, the temporary adhesive film is removed.

In S30c, a second dielectric layer is prepared on the first surface of the first glass substrate.

In S30d, laser drilling is carried out on the second dielectric layer to expose the I/O port of the chip to obtain the chip package.

In an embodiment, step S50 specifically includes steps S50a to S50f.

In S50a, a seed layer is prepared on the surface of the chip package and the inner wall of the through hole.

In S50b, a photosensitive film is attached onto the seed layer on the surface of the chip package, and exposure and development are carried out to form a patterned window.

In S50c, a first redistribution layer is prepared in the patterned window and on the inner wall of the through hole.

In S50d, a residual photosensitive film is removed, and the exposed seed layer is etched away.

In S50e, a solder mask is prepared in the through hole and on both surfaces of the chip package prepared with the first redistribution layer, and a pad region of the first redistribution layer is exposed.

In S50f, a nickel-palladium-gold layer is prepared in the pad region of the first redistribution layer, and a metal bump is implanted in the nickel-palladium-gold layer to obtain the embedded chip fan-out packaging structure.

In an embodiment, as a second scheme of the method of preparing an all-glass stacked packaging structure, in step S1, a method of preparing the embedded chip fan-out packaging structure includes steps S10 to S50.

S10, a first glass substrate is provided, and a number of first through holes and a number of embedded grooves with a design size larger than the size of a chip are opened on the first glass substrate.

In S20, a first surface of the first glass substrate is attached onto a temporary adhesive film, and the chip is attached into an embedded groove of the embedded grooves.

In S30, a dielectric layer is prepared on each of the first surface of the first glass substrate and a second surface of the first glass substrate, a first through hole of the first through holes and the gap between the chip and the first glass substrate are filled with the dielectric layer, and the dielectric layer is processed to expose an I/O port of the chip to obtain a chip package.

In S40, a second through hole is opened on the dielectric layer filled in the first through hole.

In S50, the I/O port of the chip is electrically led via the second through hole out of both surfaces of the chip package synchronously to obtain the embedded chip fan-out packaging structure.

In an embodiment, in step S20, the I/O port of the chip protrudes out of a surface of the chip, and after the chip is attached into the embedded groove with the front surface of the chip facing upwards, step S30 specifically includes steps S30a to S30d.

In S30a, a first dielectric layer is prepared on the second surface of the first glass substrate.

In S30b, the first dielectric layer is thinned by grinding to expose the I/O port of the chip.

In S30c, the temporary adhesive film is removed.

In S30d, a second dielectric layer is prepared on the first surface of the first glass substrate to obtain the chip package.

In an embodiment, in step S20, the I/O port of the chip is flush with a surface of the chip, and after the chip is attached into the embedded groove with the front surface of the chip facing upwards, step S30 specifically includes steps S30a to S30d.

In S30a, a first dielectric layer is prepared on the second surface of the first glass substrate.

In S30b, laser drilling is carried out on the first dielectric layer to expose the I/O port of the chip.

In S30c, the temporary adhesive film is removed.

In S30d, a second dielectric layer is prepared on the first surface of the first glass substrate to obtain the chip package.

In an embodiment, in step S20, the I/O port of the chip is flush with a surface of the chip, and after when the chip is attached into the embedded groove with the front surface of the chip facing downwards, step S30 specifically includes steps S30a to S30d.

In S30a, a first dielectric layer is prepared on the second surface of the first glass substrate.

In S30b, the temporary adhesive film is removed.

In S30c, a second dielectric layer is prepared on the first surface of the first glass substrate.

In S30d, laser drilling is carried out on the second dielectric layer to expose the I/O port of the chip to obtain the chip package.

In an embodiment, step S50 specifically includes steps S50a to S50f.

In S50a, a seed layer is prepared on the surface of the chip package and the inner wall of the second through hole.

In S50b, a photosensitive film is attached onto the seed layer on the surface of the chip package, and exposure and development are carried out to form a patterned window.

In S50c, a first redistribution layer is prepared in the patterned window and on the inner wall of the second through hole.

In S50d, a residual photosensitive film is removed, and the exposed seed layer is etched away.

In S50e, a solder mask is prepared in the second through hole and on both surfaces of the chip package prepared with the first redistribution layer, and a pad region of the first redistribution layer is exposed.

In S50f, a nickel-palladium-gold layer is prepared in the pad region of the first redistribution layer, and a metal bump is implanted in the nickel-palladium-gold layer to obtain the embedded chip fan-out packaging structure.

In an embodiment, in step S40, the second through hole is opened by laser on the dielectric layer filled in the first through hole.

In an embodiment, as a third scheme of the method of preparing an all-glass stacked packaging structure, a method of preparing the glass metallized circuit structure includes steps S100 to S800.

In S100, a second glass substrate is provided, and laser modification is carried out on a portion of the second glass substrate.

In S200, a photosensitive film is pressed onto both surfaces of the second glass substrate, exposure and development are carried out to form a first patterned window, and a laser-modified region of the second glass substrate is exposed from the first patterned window.

In S300, the second glass substrate is etched to form a through hole in the laser-modified region and an embedded circuit groove in a non-laser-modified region at the first patterned window.

In S400, a residual photosensitive film is removed, and a seed layer is prepared on the surface of the embedded circuit groove and the inner wall of the through hole.

In S500, a photosensitive film is pressed onto the surface of the second glass substrate and the seed layer on the surface of the embedded circuit groove, and exposure and development are carried out on the photosensitive film to form a second patterned window.

In S600, a conductive pillar is prepared in the through hole, and a second redistribution layer electrically connected to the conductive pillar is prepared in the second patterned window, where the surface of the second redistribution layer is flush with the surface of the second glass substrate.

In S700, a residual photosensitive film is removed, and flash etching is carried out on the exposed seed layer.

In S800, a solder mask is prepared on one side of the second glass substrate and the surface of a second redistribution layer corresponding to the one side of the second glass substrate to cover the one side of the second glass substrate and the corresponding second redistribution layer to obtain the glass metallized circuit structure.

In an embodiment, as a fourth scheme of the method of preparing an all-glass stacked packaging structure, a method of preparing the glass metallized circuit structure includes steps S100 to S900.

In S100, a second glass substrate is provided, and laser modification is carried out on a portion of the second glass substrate.

In S200, a photosensitive film is pressed onto both surfaces of the second glass substrate, exposure and development are carried out to form a first patterned window, and a laser-modified region of the second glass substrate is exposed from the first patterned window.

In S300, the second glass substrate is etched to form a through hole in the laser-modified region and an embedded circuit groove in a non-laser-modified region at the first patterned window.

In S400, a residual photosensitive film is removed, and a seed layer is prepared on the surface of the embedded circuit groove and the inner wall of the through hole.

In S500, a photosensitive film is pressed onto the surface of the second glass substrate and the seed layer on the surface of the embedded circuit groove, and exposure and development are carried out on the photosensitive film to form a second patterned window.

In S600, a conductive pillar is prepared in the through hole, and a second redistribution layer electrically connected to the conductive pillar is prepared in the second patterned window, where the surface of the second redistribution layer is flush with the surface of the second glass substrate.

In S700, a residual photosensitive film is removed, and flash etching is carried out on the exposed seed layer; a solder mask is prepared on one side of the second glass substrate and the surface of a second redistribution layer corresponding to the one side of the second glass substrate to cover the one side of the second glass substrate and the corresponding second redistribution layer.

In S800, (m+1) first substrate structures are prepared according to steps S100-S700, where m is a positive integer, hole opening is carried out on the solder mask of each of m first substrate structures to expose a pad region of the second redistribution layer of each of the m first substrate structures, and a metal bump is implanted in the pad region to obtain a second substrate structure serving as an intermediate.

In S900, a metal bump of one second substrate structure is coated with a nanometal paste, and the metal bump of the one second substrate structure is butt-joined and secured by sintering to the exposed second redistribution layer of a first substrate structure; then, a metal bump of another second substrate structure is coated with the nanometal paste, and the metal bump of the another second substrate structure is butt-joined and secured by sintering to the exposed second redistribution layer of the one second substrate structure; all second substrate structures are secured in the same manner; finally, the connecting material is filled between the first substrate structure and the second substrate structure and between each of two adjacent second substrate structures, and carrying out sintering to obtain the glass metallized circuit structure.

Optionally, the nanometal paste may be a nano-copper paste, a nano-silver paste or the like.

In an embodiment, in step S300, the etching rate ratio of the laser-modified region to the non-laser-modified region of the second glass substrate is 20:1.

In an embodiment, in step S400b, after the second patterned window is formed, the residual photosensitive film in the second patterned window is etched away by plasma.

In an embodiment, as a fifth scheme of the method of preparing an all-glass stacked packaging structure, a method of preparing the glass metallized circuit structure includes steps S100 to S700.

In S100, a second glass substrate is provided, and laser modification is carried out on a portion of the second glass substrate.

In S200, the second glass substrate is etched to form a through hole in a laser-modified region.

In S300, a seed layer is prepared on the inner wall of the through hole and both surfaces of the second glass substrate.

In S400, a photosensitive film is separately pressed onto the seed layer on the both surfaces of the second glass substrate, and exposure and development are carried out to form a patterned window.

In S500, a second redistribution layer is prepared in the patterned window, and a copper pillar is filled in the through hole.

In S600, a residual photosensitive film is removed, and flash etching is carried out on the exposed seed layer.

In S700, a solder mask is prepared on one side of the second glass substrate and the surface of a second redistribution layer corresponding to the one side of the second glass substrate to cover the one side of the second glass substrate and the corresponding second redistribution layer to obtain the glass metallized circuit structure.

In an embodiment, as a sixth scheme of the method of preparing an all-glass stacked packaging structure, a method of preparing the glass metallized circuit structure includes steps S100 to S900.

In S100, a second glass substrate is provided, and laser modification is carried out on a portion of the second glass substrate.

In S200, the second glass substrate is etched to form a through hole in a laser-modified region.

In S300, a seed layer is prepared on the inner wall of the through hole and both surfaces of the second glass substrate.

In S400, a photosensitive film is separately pressed onto the seed layer on the both surfaces of the second glass substrate, and exposure and development are carried out to form a patterned window.

In S500, a second redistribution layer is prepared in the patterned window, and a copper pillar connected to the second redistribution layer is filled in the through hole.

In S600, a residual photosensitive film is removed, and flash etching is carried out on the exposed seed layer.

In S700, a solder mask is prepared on one side of the second glass substrate and the surface of a second redistribution layer corresponding to the one side of the second glass substrate to cover the one side of the second glass substrate and the corresponding second redistribution layer.

In S800, (m+1) first substrate structures are prepared according to steps S100-S700, where m is a positive integer, hole opening is carried out on the solder mask of each of m first substrate structures to expose a pad region of the second redistribution layer of each of the m first substrate structures, and a metal bump is implanted in the pad region to obtain a second substrate structure serving as an intermediate.

In S900, a metal bump of one second substrate structure is coated with a nanometal paste, and the metal bump of the one second substrate structure is butt-joined and secured by sintering to the exposed second redistribution layer of a first substrate structure; then, a metal bump of another second substrate structure is coated with the nanometal paste, and the metal bump of the another second substrate structure is butt-joined and secured by sintering to the exposed second redistribution layer of the one second substrate structure; all second substrate structures are secured in the same manner; finally, the connecting material is filled between the first substrate structure and the second substrate structure and between each of two adjacent second substrate structures, and sintering is carried out on the connecting material to obtain the glass metallized circuit structure.

Optionally, the nanometal paste in the present application may be a nano-copper paste, a nano-silver paste or the like.

Optionally, the metal bump in the present application may be a tin ball, a conductive pillar or the like.

In another aspect, the present application further provides an all-glass stacked packaging structure prepared by using the preparation method. The all-glass stacked packaging structure includes an embedded chip fan-out packaging structure and a glass metallized circuit structure that are stacked vertically. A metal bump of the embedded chip fan-out packaging structure is connected to the exposed second redistribution layer of the glass metallized circuit structure, and the gap between the embedded chip fan-out packaging structure and the glass metallized circuit structure is filled with a connection layer formed by sintering a connecting material.

The beneficial effects of the present application are as follows: In the present application, after an embedded chip fan-out packaging structure is butt-joined to a glass metallized circuit structure, a metal bump of the embedded chip fan-out packaging structure is secured by welding to a redistribution layer of the glass metallized circuit structure, the gap between the embedded chip fan-out packaging structure and the glass metallized circuit structure is then filled with a connecting material, and sintering is carried out on the connecting material to enable the embedded chip fan-out packaging structure to be fixedly connected to the glass substrate of the glass metallized circuit structure by sintering the connecting material. By carrying out securing by sintering the connecting material, the stability of the electrical connection between the embedded chip fan-out packaging structure and the glass metallized circuit structure can be further improved, thereby preparing an all-glass stacked packaging structure with a more stable structure.

### BRIEF DESCRIPTION OF DRAWINGS

FIG. 1.1 is a section view when a chip is embedded into an embedded groove of a first glass substrate according to Embodiment 1 of the present application.

FIG. 1.2 is a section view after a first dielectric layer is pressed according to Embodiment 1 of the present application.

FIG. 1.3 is a section view after through holes are opened on a chip package according to Embodiment 1 of the present application.

FIG. 1.4 is a section view after a first redistribution layer is prepared according to Embodiment 1 of the present application.

FIG. 1.5 is a section view after green oil is brushed according to Embodiment 1 of the present application.

FIG. 1.6 is a section view after nickel-palladium-gold is melted according to Embodiment 1 of the present application.

FIG. 1.7 is a section view after metal bumps are implanted in a nickel-palladium-gold layer according to Embodiment 1 of the present application.

FIG. 1.8 is a section view of a second glass substrate according to Embodiment 1 of the present application.

FIG. 1.9 is a schematic view of the center line of a laser-modified region on the second glass substrate according to Embodiment 1 of the present application.

FIG. 1.10 is a section view after a first photosensitive film is pressed onto both surfaces of the second glass substrate according to Embodiment 1 of the present application.

FIG. 1.11 is a section view after exposure and development are carried out on the photosensitive film according to Embodiment 1 of the present application.

FIG. 1.12 is a section view after the second glass substrate is etched according to Embodiment 1 of the present application.

FIG. 1.13 is a section view after the residual photosensitive film is removed according to Embodiment 1 of the present application.

FIG. 1.14 is a section view after copper pillars and a second redistribution layer are prepared according to Embodiment 1 of the present application.

FIG. 1.15 is a section view of a glass metallized circuit structure according to Embodiment 1 of the present application.

FIG. 1.16 is a section view after the embedded chip fan-out packaging structure is butt-joined and welded to the glass metallized circuit structure according to Embodiment 1 of the present application.

FIG. 1.17 is a section view of an all-glass stacked packaging structure according to Embodiment 1 of the present application.

FIG. 2.1 is a section view after a second glass substrate is etched according to Embodiment 2 of the present application.

FIG. 2.2 is a section view after a photosensitive film is attached according to Embodiment 2 of the present application.

FIG. 2.3 is a section view after exposure and development are carried out on the photosensitive film according to Embodiment 2 of the present application.

FIG. 2.4 is a section view after copper pillars and a second redistribution layer are prepared according to Embodiment 2 of the present application.

FIG. 2.5 is a section view of a glass metallized circuit structure according to Embodiment 2 of the present application.

FIG. 3.1 is a section view when a chip is embedded into an embedded groove of a first glass substrate according to Embodiment 3 of the present application.

FIG. 3.2 is a section view after a first dielectric layer is pressed according to Embodiment 3 of the present application.

FIG. 3.3 is a section view after through holes are opened on a chip package according to Embodiment 3 of the present application.

FIG. 3.4 is a section view after a redistribution layer is prepared according to Embodiment 3 of the present application.

FIG. 3.5 is a section view after green oil is brushed according to Embodiment 3 of the present application.

FIG. 3.6 is a section view after nickel-palladium-gold is melted according to Embodiment 3 of the present application.

FIG. 3.7 is a section view after metal bumps are implanted in a nickel-palladium-gold layer according to Embodiment 3 of the present application.

FIG. 3.8 is a section view of a second substrate structure according to Embodiment 3 of the present application.

FIG. 3.9 is a section view of a glass metallized circuit structure according to Embodiment 3 of the present application.

FIG. 3.10 is a section view after the embedded chip fan-out packaging structure is butt-joined and welded to the glass metallized circuit structure according to Embodiment 3 of the present application.

FIG. 3.11 is a section view of an all-glass stacked packaging structure according to Embodiment 3 of the present application.

FIG. 4.1 is a section view when a chip is embedded into an embedded groove of a first glass substrate according to Embodiment 4 of the present application.

FIG. 4.2 is a section view after a first dielectric layer is pressed according to Embodiment 4 of the present application.

FIG. 4.3 is a section view after through holes are opened on a chip package according to Embodiment 4 of the present application.

FIG. 4.4 is a section view after a first redistribution layer is prepared according to Embodiment 4 of the present application.

FIG. 4.5 is a section view after green oil is brushed according to Embodiment 4 of the present application.

FIG. 4.6 is a section view after nickel-palladium-gold is melted according to Embodiment 4 of the present application.

FIG. 4.7 is a section view after metal bumps are implanted in the nickel-palladium-gold layer according to Embodiment 4 of the present application.

FIG. 4.8 is a section view after the embedded chip fan-out packaging structure is butt-joined and welded to the glass metallized circuit structure according to Embodiment 4 of the present application.

FIG. 4.9 is a section view of an all-glass stacked packaging structure according to Embodiment 4 of the present application.

FIG. 5.1 is a section view when a chip is embedded into an embedded groove of a first glass substrate according to Embodiment 6 of the present application.

FIG. 5.2 is a section view after a first dielectric layer and a second dielectric layer pressed according to Embodiment 6 of the present application.

FIG. 5.3 is a section view after a second through hole is opened on a chip package according to Embodiment 6 of the present application.

FIG. 5.4 is a section view after a first redistribution layer is prepared according to Embodiment 6 of the present application.

FIG. 5.5 is a section view after green oil is brushed according to Embodiment 6 of the present application.

FIG. 5.6 is a section view after nickel-palladium-gold is melted according to Embodiment 6 of the present application.

FIG. 5.7 is a section view after metal bumps are implanted in the nickel-palladium-gold layer according to Embodiment 6 of the present application.

FIG. 5.8 is a section view of a second substrate structure according to Embodiment 6 of the present application.

FIG. 5.9 is a section view of a glass metallized circuit structure according to Embodiment 6 of the present application.

FIG. 5.10 is a section view after the embedded chip fan-out packaging structure is butt-joined and welded to the glass metallized circuit structure according to Embodiment 6 of the present application.

FIG. 5.11 is a section view of an all-glass stacked packaging structure according to Embodiment 6 of the present application.

### DETAILED DESCRIPTION

The technical schemes of the present application are further described below through embodiments.

If not specified, various raw materials of the present application may be commercially available or prepared according to conventional methods in the art.

In the present application, through the double-sided fan-out packaging structure, the interconnection distance can be effectively reduced, the three-dimensional stacking can be easily implemented, and great advantages such as lower loss and higher efficiency in electrical interconnection performance are gained, thereby greatly reducing the difficulty of the packaging process and lowering the packaging cost.

### Embodiment 1

The method of preparing an all-glass stacked packaging structure in Embodiment 1 is described below.

### I. Preparation of an Embedded Chip Fan-Out Packaging Structure

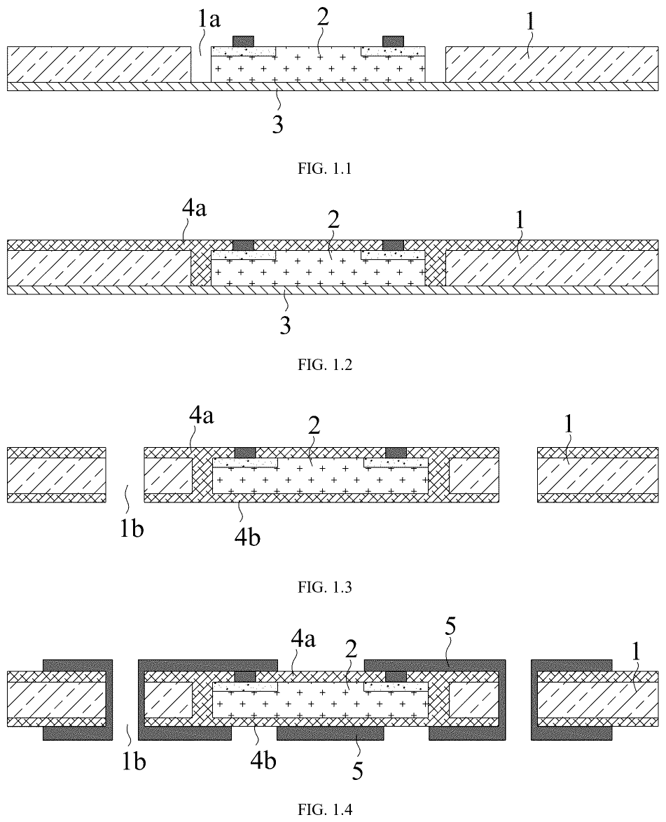

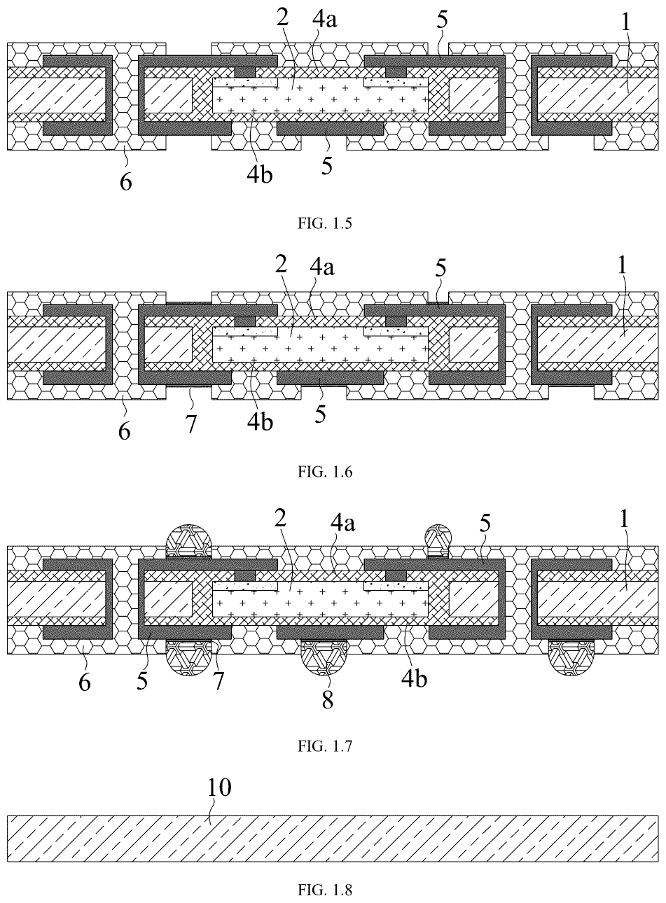

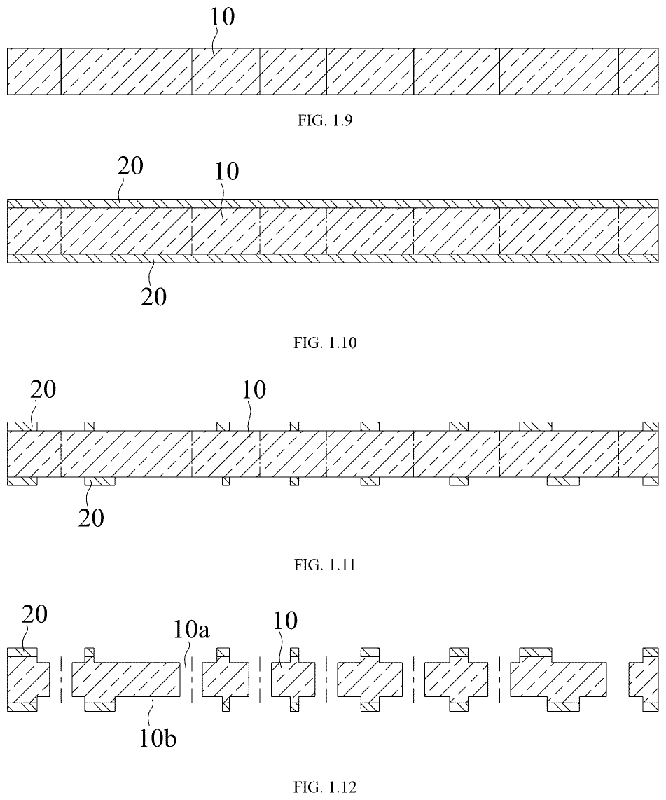

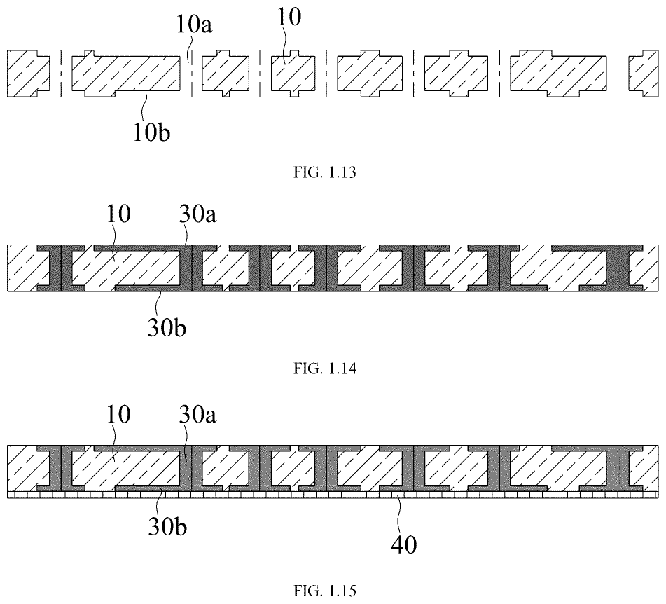

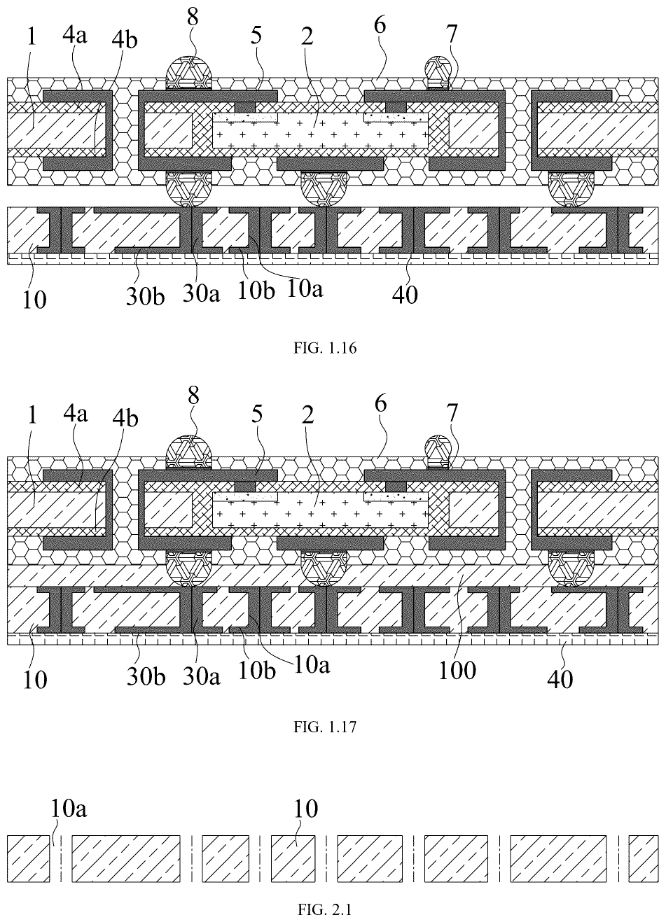

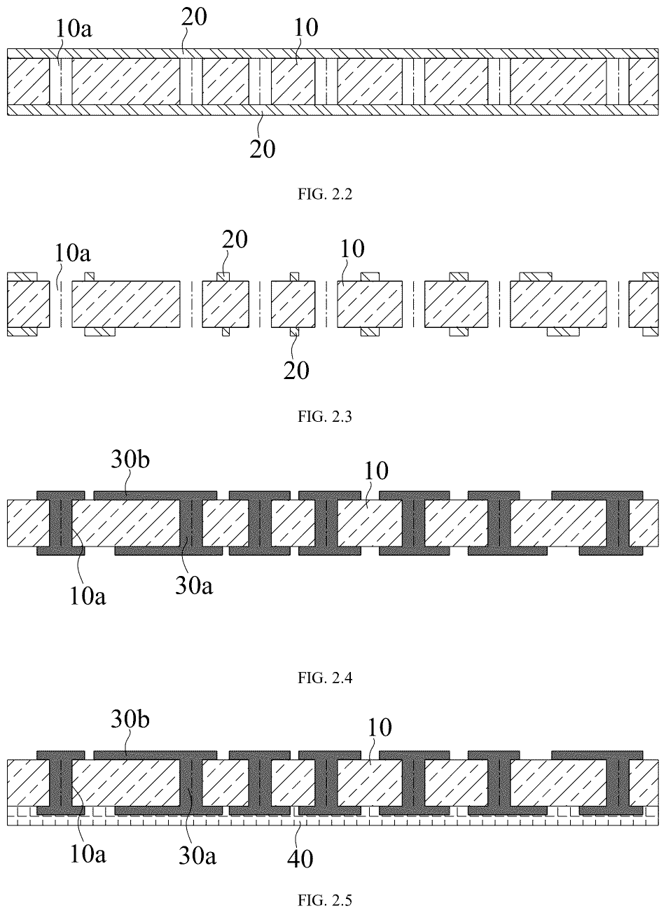

1. A first glass substrate 1 is provided, and a number of embedded grooves 1a (in the form of through holes) with a design size larger than the size of a chip 2 are opened on the first glass substrate 1.
2. The lower surface (the first surface) of the first glass substrate 1 is attached onto a temporary adhesive film 3.
3. A number of chips 2 are provided, an I/O port (bump pillar) of a chip 2 of the chips 2 protrudes out of the surface of the chip 2, and the chip 2 is attached onto the temporary adhesive film 3 in an embedded groove 1a of the embedded grooves 1a with the front surface of the chip 2 facing upwards (that is, the I/O port faces up), as shown in FIG. 1.1.
4. A first dielectric layer 4a is pressed onto the upper surface (the second surface) of the first glass substrate 1, the gap between the chip 2 and the first glass substrate 1 is filled with the first dielectric layer 4a, and the first dielectric layer 4a is thinned by grinding to expose the I/O port of the chip 2, as shown in FIG. 2.2.
5. The temporary adhesive film 3 on the first surface of the first glass substrate 1 is removed.
6. A second dielectric layer 4b is prepared on the first surface of the first glass substrate 1 to obtain a chip package.
7. Hole opening is carried out on the chip package by mechanical drilling to form a number of through holes 1b on the chip package, as shown in FIG. 1.3.
8. A seed layer is synchronously prepared by vacuum sputtering on the inner wall of a through hole 1b of the through holes 1b, the side of the first dielectric layer 4a away from the first glass substrate 1 and the side of the second dielectric layer 4b away from the first glass substrate 1.
9. A photosensitive film is attached onto the seed layer on the first dielectric layer 4a and the seed layer on the second dielectric layer 4b, and exposure and development are carried out to form a patterned window with part of the seed layer exposed.
10. A first redistribution layer 5 is synchronously prepared by electroplating on the surface of the seed layer on the inner wall of the through hole 1b and in the patterned window, as shown in FIG. 1.4.
11. The residual photosensitive film is removed to expose part of the seed layer, and the exposed seed layer is etched.
12. Green oil is brushed in the through hole 1b prepared with the seed layer and the first redistribution layer 5, on the surface of the first dielectric layer 4a, on the surface of the second dielectric layer 4b and on the surface of the first redistribution layer 5, and exposure and development are carried out after the green oil is cured to form a solder mask 6 that exposes the pad region of the first redistribution layer 5, as shown in FIG. 1.5, where the first dielectric layer 4a and the second dielectric layer 4b form a dielectric layer.
13. Nickel-palladium-gold is melted in the pad region of the first redistribution layer 5 to obtain a nickel-palladium-gold layer 7, as in FIG. 1.6.
14. A metal bump 8 is implanted in the nickel-palladium-gold layer to obtain an embedded chip fan-out packaging structure, as shown in FIG. 1.7.

### II. Preparation of a Glass Metallized Circuit Structure

1. A second glass substrate 10 shown in FIG. 1.8 is provided, and laser modification is carried out on a portion (a target region) of the second glass substrate 10. Specifically, a to-be-opened region of the second glass substrate 10 is delimited as a target region (a centerline region, FIG. 1.9), the second glass substrate 10 is then placed under a Ti:Sapphire femtosecond laser, and annular illumination is carried out on the target region with a pulse energy of 2 uJ and at a laser scanning speed of 0.35 mm/s such that the second glass substrate 10 in the target region is modified.
2. A shown in FIG. 1.10, a photosensitive film 20 is pressed onto both surfaces of the second glass substrate 10, exposure and development are carried out to form a first patterned window shown in FIG. 1.11, and the laser-modified region of the second glass substrate 10 is exposed from the first patterned window.
3. The second glass substrate 10 is etched, where the etching rate ratio of the laser-modified region to the non-laser-modified region of the second glass substrate 10 is controlled to be 20:1, to form a through hole 10a in the laser-modified region and an embedded circuit groove 10b in the non-laser-modified region at the first patterned window, where the through hole 10a is connected to the embedded circuit groove 10b, as shown in FIG. 1.12. Specifically, the second glass substrate 10 is sprayed with an etching solution (hydrofluoric acid +additives) at 30° C. for 30 minutes so that the glass in the laser-modified region falls off to form the through hole 10a and the region around the through hole that is exposed from the photosensitive film 20 falls off to form the embedded circuit groove 10b.
4. The residual photosensitive film 20 is removed (FIG. 1.13), and a seed layer is prepared on the surface of the embedded circuit groove 10b and the inner wall of the through hole 10a.
5. A photosensitive film is pressed onto the surface of the second glass substrate 10 and the seed layer on the surface of the embedded circuit groove 10b, and exposure and development are carried out on the photosensitive film to form a second patterned window.
6. The residual photosensitive film 20 in the second patterned window is etched away by plasma.
7. A copper pillar 30a is deposited by electroplating in the through hole 10a, and a second redistribution layer 30b electrically connected to the copper pillar 30a is prepared in the second patterned window, where the surface of the second redistribution layer 30b is flush with the surface of the second glass substrate 10.
8. The residual photosensitive film is removed, and flash etching is carried out on the exposed seed layer, as shown in FIG. 1.14, where the surface of the second redistribution layer 30b is flush with the surface of the second glass substrate 10.
9. Green oil is brushed on one side of the second glass substrate 10 and the surface of the second redistribution layer 30b corresponding to the one side of the second glass substrate 10, and a solder mask 40 covering the one side of the second glass substrate 10 and the corresponding second redistribution layer 30b is formed after the green oil is cured to obtain a glass metallized circuit structure shown in FIG. 1.15.
   III. Stacking, Welding, Filling with Na₂O·SiO₂, and Sintering
1. The metal bump 8 of the embedded chip fan-out packing structure is butt-joined and secured by welding to the second redistribution layer 30b of the glass metallized circuit structure, as shown in FIG. 1.16.
2. The gap between the embedded chip fan-out packaging structure and the glass metallized circuit structure is filled with Na₂O·SiO₂, and sintering is carried out on Na₂O·SiO₂ at 180° C. for 3 hours to obtain an all-glass stacked packaging structure shown in FIG. 1.17.

As shown in FIG. 1.17, the all-glass stacked packaging structure in Embodiment 1 includes an embedded chip fan-out packaging structure and a glass metallized circuit structure that are stacked vertically. The metal bump 8 of the embedded chip fan-out packaging structure is connected to the second redistribution layer 30b of the glass metallized circuit structure, and the gap between the embedded chip fan-out packaging structure and the glass metallized circuit structure is filled with a connection layer 100 formed by sintering Na₂O·SiO₂.

As shown in FIG. 1.17, the embedded chip fan-out packaging structure includes a first glass substrate 1, a number of chips 2, a seed layer, a first redistribution layer 5, a solder mask 6, a nickel-palladium gold layer 7 and metal bumps 8.

A number of embedded grooves 1a and a number of through holes 1b are opened on the first glass substrate 1.

A chip 2 is fixed in an embedded groove 1a through the first dielectric layer 4a above the first glass substrate 1 and the second dielectric layer 4b below the first glass substrate 1, the I/O port of the chip 2 protrudes out of the surface of the chip 2 and is exposed from the first dielectric layer 4a, and the I/O port of the chip 2 is flush with the surface of the first dielectric layer 4a, where the first dielectric layer 4a and the second dielectric layer 4b are partially embedded in the gap between the chip 2 and the embedded groove la, respectively.

The seed layer is located on the inner wall of the through hole 1b, the surface of the first dielectric layer 4a and the surface of the second dielectric layer 4b and is electrically connected to the I/O port of the chip 2. In an embodiment, the seed layer is located on the inner wall of the through hole 1b, the upper surface of the first dielectric layer 4a and the lower surface of the second dielectric layer 4b.

The first redistribution layer 5 is located above the seed layer. In an embodiment, the first redistribution layer 5 is located on the surface of the seed layer on the inner wall of the through hole 1b and the surface of the seed layer on each of both surfaces of the chip package.

The solder mask 6 is filled in the through hole 1b and covers the surfaces of the first redistribution layer 5, the first dielectric layer 4a and the second dielectric layer 4b, and the pad region of the first redistribution layer 5 is exposed from the solder mask 6.

The nickel-palladium-gold layer 7 is located in the pad region of the first redistribution layer 5 and is electrically connected to the metal bump 8.

As shown in FIG. 1.15, the glass metallized circuit structure includes a second glass substrate 10, an embedded circuit and a solder mask 40.

The second glass substrate 10 is made of glass. A through hole 10a and an embedded circuit groove 10b that is located on both surfaces of the second glass substrate 10 are opened on the second glass substrate 10, and the embedded circuit groove 10b is connected to the through hole 10a.

The embedded circuit includes a conductive pillar embedded into the through hole 10a and a circuit layer embedded into the embedded circuit groove 10b. The conductive pillar is electrically connected to the circuit layer, and the surface of the circuit layer is flush with the surface of the second glass substrate 10.

The conductive pillar includes a first seed layer covering the inner wall of the through hole 10a and a copper pillar 30a that is filled in the through hole 10a, and the copper pillar 30a is connected to the first seed layer. The circuit layer includes a second seed layer located in the embedded circuit groove 10b and a second redistribution layer 30b (a copper layer) located on the surface of the second seed layer, and the second redistribution layer 30b is electrically connected to the copper pillar 30a.

The solder mask 40 covers one side of the second glass substrate 10 and the second redistribution layer 30b on the one side.

The first seed layer and the second seed layer form a seed layer and are integrally formed by vacuum sputtering.

The copper pillar 30a and the second redistribution layer 30b are integrally deposited by electroplating.

In an embodiment, the second glass substrate 10 of the glass metallized circuit structure is connected to the embedded chip fan-out packaging structure via the connection layer 100 formed by sintering Na₂O·SiO₂.

### Embodiment 2

The method of preparing an all-glass stacked packaging structure in Embodiment 2 is described below.

I. Preparation of an Embedded Chip Fan-Out Packaging Structure The method of preparing the embedded chip fan-out packaging structure in Embodiment 2 is basically the same as the preparation method in Embodiment 1 (reference is made to the accompanying drawings of Embodiment 1, and the same components keep the same reference numerals). The differences are that in Embodiment 2, the I/O port (a ubm) of the chip 2 is flush with the surface of the chip 2, and the chip 2 is attached onto the temporary adhesive film 3 in the embedded groove 1a with the front surface of the chip facing upwards (that is, the I/O port faces up); the first dielectric layer 4a is pressed onto the upper surface (the second surface) of the first glass substrate 1, and laser drilling is carried out on the first dielectric layer 4a by aligning the I/O port of the chip 2 to expose the I/O port of the chip 2; the temporary adhesive film 3 on the first surface of the first glass substrate 1 is removed; the second dielectric layer 4b is pressed onto the first surface of the first glass substrate 1 to obtain the chip package. The subsequent steps of Embodiment 2 are the same as to the steps of Embodiment 1. The embedded chip fan-out packaging structure prepared here is also basically the same as the embedded chip fan-out packaging structure prepared in Embodiment 1, and the details will not be repeated here.
II. Preparation of a Glass Metallized Circuit Structure In S10, a second glass substrate 10 shown in FIG. 1.8 is provided, and laser modification is carried out on a portion of the second glass substrate 10. Specifically, a to-be-opened region of the second glass substrate 10 is delimited as a target region (a centerline region, FIG. 1.9), the second glass substrate 10 is then placed under a Ti:Sapphire femtosecond laser, and annular illumination is carried out on the target region with a pulse energy of 2 uJ and at a laser scanning speed of 0.35 mm/s such that the substrate in the target region is modified.

In S20, the second glass substrate 10 is etched to form a through hole 10a shown in FIG. 2.1 in the laser-modified region. Specifically, the second glass substrate 10 is sprayed with an etching solution (hydrofluoric acid+additives) at 30° C. for 30 minutes so that the glass in the laser-modified region falls off to form the through hole 10a.

In S30, a seed layer (not shown) is prepared by vacuum sputtering on the inner wall of the through hole la and the both surfaces of the second glass substrate 10, where the seed layer is mad of Ti/Cu alloy.

In S40, a photosensitive film 20 (FIG. 2.2) is separately pressed onto the seed layer on both surfaces of the second glass substrate 10, and exposure and development are carried out on the photosensitive film 20 to form a patterned window (FIG. 2.3), where the seed layer is partially exposed from the photosensitive film 20.

In S50, a copper pillar 30a is filled in the through hole 10a, and a second redistribution layer 30b (a copper layer) electrically connected to the copper pillar 30a is prepared in the patterned window.

In S60, the residual photosensitive film 20 is removed, and flash etching is carried out on the seed layer exposed from the second redistribution layer 30b, as shown in FIG. 2.4.

In S70, green oil is brushed on one side of the second glass substrate 10 and the surface of the second redistribution layer 30b corresponding to the one side of the second glass substrate 10, and a solder mask 40 covering the one side of the second glass substrate 10 and the corresponding second redistribution layer 30b is formed after the green oil is cured to obtain a glass metallized circuit structure shown in FIG. 2.5.

III. Stacking, Welding, Filling with Na₂O·1.5SiO₂, and sintering
1. The metal bump 8 of the embedded chip fan-out packing structure is butt-joined and secured by welding to the second redistribution layer 30b of the glass metallized circuit structure.
2. The gap between the embedded chip fan-out packaging structure and the glass metallized circuit structure is filled with Na₂O·1.5SiO₂, and sintering is carried out on Na₂O·1.5SiO₂ at 200° C. for 2 hours to obtain an all-glass stacked packaging structure.

The all-glass stacked packaging structure in Embodiment 2 includes an embedded chip fan-out packaging structure and a glass metallized circuit structure that are stacked vertically. The metal bump 8 of the embedded chip fan-out packaging structure is connected to the second redistribution layer 30b of the glass metallized circuit structure, and the gap between the embedded chip fan-out packaging structure and the glass metallized circuit structure is filled with a connection layer 100 formed by sintering Na₂O·1.5SiO₂.

The structure of the embedded chip fan-out packaging structure is basically the same as the embedded chip fan-out packaging structure prepared in Embodiment 1, and the details will not be repeated here.

As shown in FIG. 2.5, the glass substrate metallized structure in Embodiment 2 includes a second glass substrate 10, a conductive pillar, a circuit layer and a solder mask 40.

The second glass substrate 10 is made of glass. A through hole 10a is opened on the second glass substrate 10.

The conductive pillar includes a first seed layer and a copper pillar 30a. The first seed layer covers the inner wall of the through hole 10a. The copper pillar 30a is filled in the through hole 10a covered with the first seed layer on the inner wall.

The circuit layer includes a second seed layer and a second redistribution layer 30b. The second seed layer is located on both surfaces of the second glass substrate 10 and is electrically connected to the first seed layer. The second redistribution layer 30b is located on the second seed layer on both surfaces of the second glass substrate 10 and the copper pillar 30a and is electrically connected to the copper pillar 30a.

The solder mask 40 covers one side of the second glass substrate 10 and the second redistribution layer 30b on the one side.

The first seed layer and the second seed layer form a seed layer and are integrally formed by vacuum sputtering. The copper pillar 30a and the second redistribution layer 30b are integrally deposited by electroplating.

In an embodiment, the glass substrate of the glass metallized circuit structure is connected to the embedded chip fan-out packaging structure via the connection layer 100 formed by sintering Na₂O·1.5SiO₂.

### Embodiment 3

The method of preparing an all-glass stacked packaging structure in Embodiment 3 is described below.

### I. Preparation of an Embedded Chip Fan-Out Packaging Structure

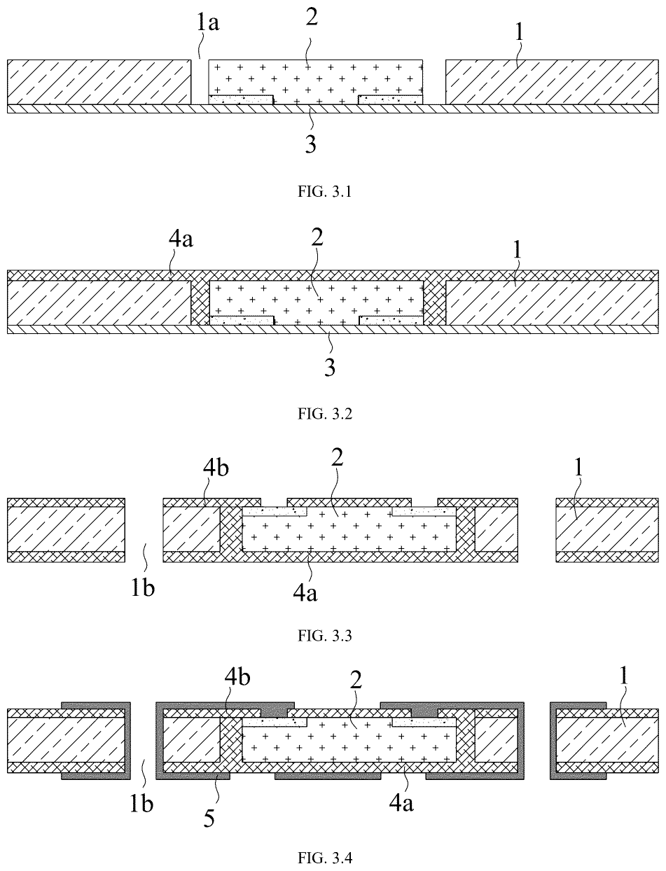

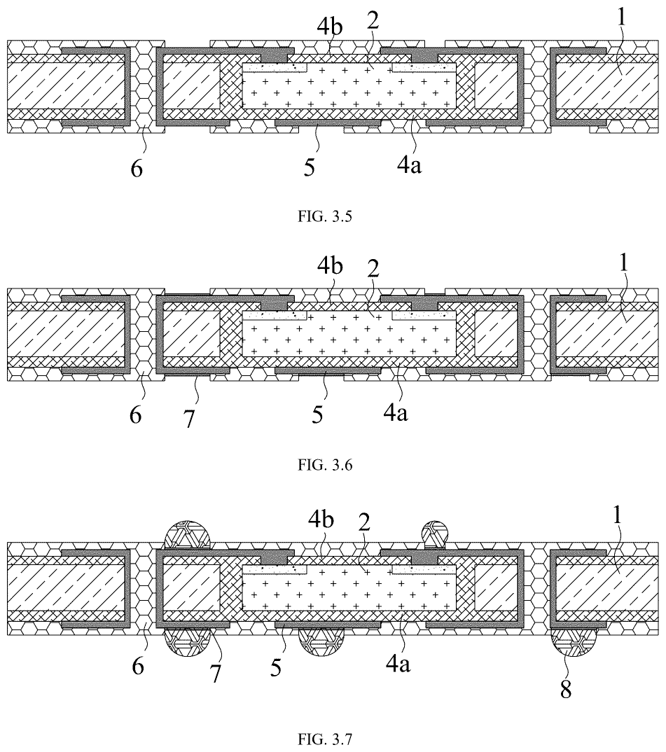

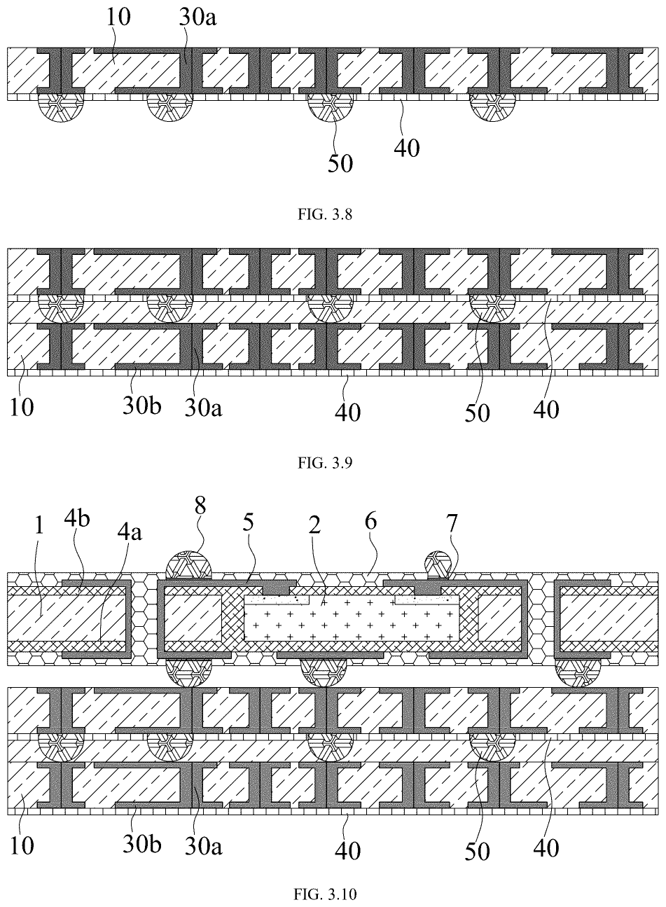

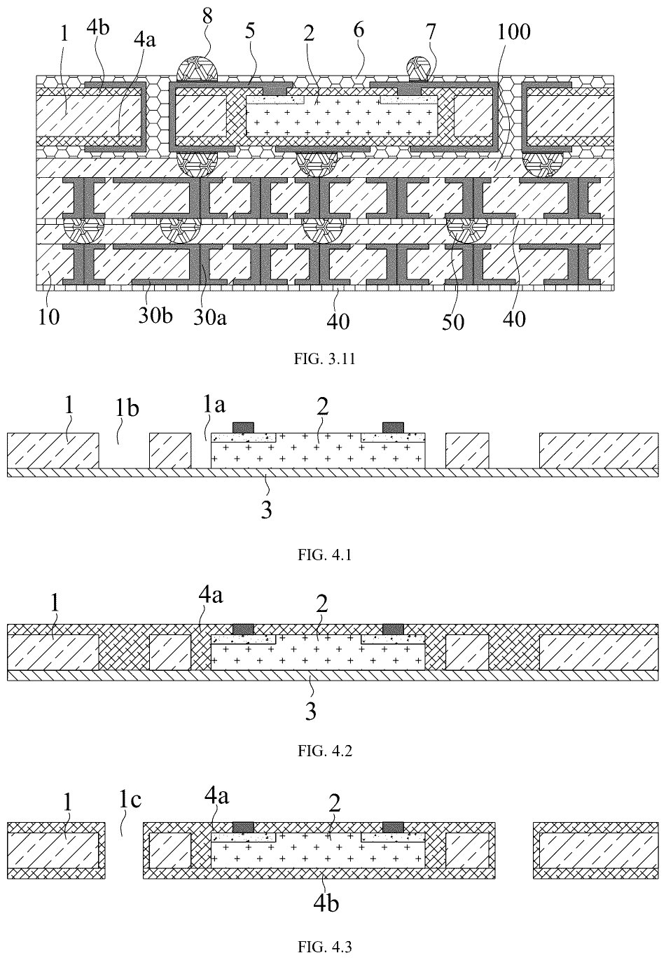

1. A first glass substrate 1 is provided, and a number of embedded grooves 1a (in the form of through holes) with a design size larger than the size of a chip 2 are opened on the first glass substrate 1.
2. The lower surface (the first surface) of the first glass substrate 1 is attached onto a temporary adhesive film 3.
3. The I/O port (a ubm) of the chip 2 is flush with the surface of the chip 2, and the chip 2 is attached onto the temporary adhesive film 3 in an embedded groove 1a of the embedded grooves la with the front surface of the chip 2 facing downwards (that is, the I/O port faces down), as shown in FIG. 3.1.
4. A first dielectric layer 4a is pressed onto the upper surface (the second surface) of the first glass substrate 1, and the gap between the chip 2 and the embedded groove 1a is filled with the first dielectric layer 4a, as shown in FIG. 3.2.
5. The temporary adhesive film 3 on the first surface of the first glass substrate 1 is removed.
6. The first glass substrate 1 is flipped, a second dielectric layer 4b is pressed on the first surface of the first glass substrate 1, and laser drilling is carried out on the second dielectric layer 4b to expose the I/O port of the chip 2 to obtain a chip package.
7. Hole opening is carried out on the chip package by mechanical drilling to form a number of through holes 1b on the chip package, as shown in FIG. 3.3.
8. A seed layer is synchronously prepared by vacuum sputtering on the inner wall of a through hole 1b of the through holes 1b, the side of the first dielectric layer 4a away from the first glass substrate 1 and the side of the second dielectric layer 4b away from the first glass substrate 1.
9. A photosensitive film is attached onto the seed layer on the first dielectric layer 4a and the seed layer on the second dielectric layer 4b, and exposure and development are carried out to form a patterned window with part of the seed layer exposed.
10. A first redistribution layer 5 is synchronously prepared by electroplating on the surface of the seed layer on the inner wall of the through hole 1b and in the patterned window, as shown in FIG. 3.4.
11. The residual photosensitive film is removed to expose part of the seed layer, and the exposed seed layer is etched.
12. Green oil is brushed in the through hole 1b prepared with the seed layer and the first redistribution layer 5, on the surface of the first dielectric layer 4a, on the surface of the second dielectric layer 4b and on the surface of the first redistribution layer 5, and exposure and development are carried out after the green oil is cured to form a solder mask 6 that exposes the pad region of the first redistribution layer 5, as shown in FIG. 3.5.
13. Nickel-palladium-gold is melted in the pad region of the first redistribution layer 5 to obtain a nickel-palladium-gold layer 7, as in FIG. 3.6.
14. A metal bump 8 is implanted in the nickel-palladium-gold layer 7 to obtain an embedded chip fan-out packaging structure shown in FIG. 3.7.

### II. Preparation of a Glass Metallized Circuit Structure

The glass-metallized circuit structure in Embodiment 3 is formed by connecting one layer of first substrate structure and one layer of second substrate structure, and the method for preparing the first substrate structure is exactly the same as steps 1 to 9 in the method for preparing the glass-metallized circuit structure in Embodiment 1.

After two first substrate structures (referring to FIG. 1.15) are prepared, the second substrate structure is prepared using one of the two first substrate structures specifically according to the following steps.

Hole opening is carried out on the solder mask 40 of the first substrate structure to expose a pad region of the second redistribution layer 30b of the first substrate structure, and a metal bump 50 is implanted in the pad region to obtain a second substrate structure serving as an intermediate, as shown in FIG. 3.8.

The first substrate structure is connected to the second substrate structure specifically according to the following steps.

The metal bump 50 of the second substrate structure is coated with a nanometal paste and is butt-joined and secured by sintering to the exposed second redistribution layer 30b of the first substrate structure; the connecting material described in Embodiment 1 is filled between the first substrate structure and the second substrate structure and between two adjacent second substrate structures, and sintering and securing are carried out according to the sintering method described in Embodiment 1 to obtain the glass metallized circuit structure shown in FIG. 3.9.

III. Stacking, Welding, Filling with Silica Gel, and Sintering
1. As shown in FIG. 3.10, the metal bump 8 of the embedded chip fan-out packing structure is butt-joined and secured by welding to the second redistribution layer 30b of the glass metallized circuit structure.
2. The gap between the embedded chip fan-out packaging structure and the glass metallized circuit structure is filled with silica gel, and sintering is carried out on silica gel at 160° C. for 4 hours to form a connection layer 100, thereby obtaining an all-glass stacked packaging structure shown in FIG. 3.11.

As shown in FIG. 3.11, the all-glass stacked packaging structure in Embodiment 3 includes an embedded chip fan-out packaging structure and a glass metallized circuit structure that are stacked vertically. The metal bump 8 of the embedded chip fan-out packaging structure is connected to the second redistribution layer 30b of the glass metallized circuit structure, and the gap between the embedded chip fan-out packaging structure and the glass metallized circuit structure is filled with a connection layer 100 formed by sintering silica gel.

The embedded chip fan-out packaging structure includes a first glass substrate 1, a number of chips 2, a seed layer, a first redistribution layer 5, a solder mask 6, a nickel-palladium gold layer 7 and metal bumps 8.

A number of embedded grooves 1a and a number of through holes 1b are opened on the first glass substrate 1.

A chip 2 is fixed in an embedded groove 1a through the first dielectric layer 4a above the first glass substrate 1 and the second dielectric layer 4b below the first glass substrate 1, and the I/O port of the chip 2 is flush with the surface of the chip 2 and is exposed from the first dielectric layer 4a (a hole structure for exposing the I/O port of the chip 2 is opened on the second dielectric layer 4b), where the first dielectric layer 4a and the second dielectric layer 4b are partially embedded in the gap between the chip 2 and the embedded groove la, respectively, and the first dielectric layer 4a and the second dielectric layer 4b form a dielectric layer.

The seed layer is located on the inner wall of the through hole 1b and the surface of the first dielectric layer 4a and is electrically connected to the I/O port of the chip 2. In an embodiment, the seed layer is located on the inner wall of the through hole 1b, on the upper surface of the first dielectric layer 4a, on the lower surface of the second dielectric layer 4b and in the hole structure on the second dielectric layer 4b.

The first redistribution layer 5 is located above the seed layer. In an embodiment, the first redistribution layer 5 is located on the surface of the seed layer on the inner wall of the through hole 1b and the surface of the seed layer on each of both surfaces of the chip package.

The solder mask 6 is filled in the through hole 1b and covers the surfaces of the first redistribution layer 5, the first dielectric layer 4a and the second dielectric layer 4b, and the pad region of the first redistribution layer 5 is exposed from the solder mask 6.

The nickel-palladium-gold layer 7 is located in the pad region of the first redistribution layer 5 and is electrically connected to the metal bump 8.

The glass substrate metallized structure includes a first substrate structure, a second substrate structure and a connection layer filled between the first substrate structure and the second substrate structure.

The first substrate structure includes a second glass substrate 10, a conductive pillar, a circuit layer and a solder mask 40.

The second glass substrate 10 is made of glass. A through hole 10a is opened on the second glass substrate 10.

The conductive pillar includes a first seed layer and a copper pillar 30a. The first seed layer covers the inner wall of the through hole 10a. The copper pillar 30a is filled in the through hole 10a covered with the first seed layer on the inner wall.

The circuit layer includes a second seed layer and a second redistribution layer 30b. The second seed layer is located on both surfaces of the second glass substrate 10 and is electrically connected to the first seed layer. The second redistribution layer 30b is located on the second seed layer on both surfaces of the second glass substrate 10 and the copper pillar 30a and is electrically connected to the copper pillar 30a.

The solder mask 40 covers one side of the second glass substrate 10 and the second redistribution layer 30b on the one side.

The second substrate structure is basically the same as the first substrate structure described above, and the difference is that in the second substrate structure, the solder mask 40 is provided with a hole structure for exposing the pad region of the second redistribution layer 30b and a metal bump 50 secured by welding to the pad region of the second redistribution layer 30b.

The metal bump 50 of the second substrate structure is electrically connected to the second redistribution layer 30b of the first substrate structure via a connection portion formed by sintering the nano-copper paste.

In an embodiment, the second glass substrate 10 of the glass metallized circuit structure is connected to the embedded chip fan-out packaging structure via the connection layer 100 formed by sintering silica gel.

In another embodiment, the first substrate structure is secured by sintering to the metal bump of the second substrate structure and then secured by welding to the metal bump of the embedded chip fan-out packaging structure, and a connecting material is synchronously filled in the gap between the first substrate structure and the second substrate structure and the gap between the second substrate structure and the embedded chip fan-out packaging structure and then synchronously sintered.

### Embodiment 4

The method of preparing an all-glass stacked packaging structure in Embodiment 4 is described below.

### I. Preparation of an Embedded Chip Fan-Out Packaging Structure

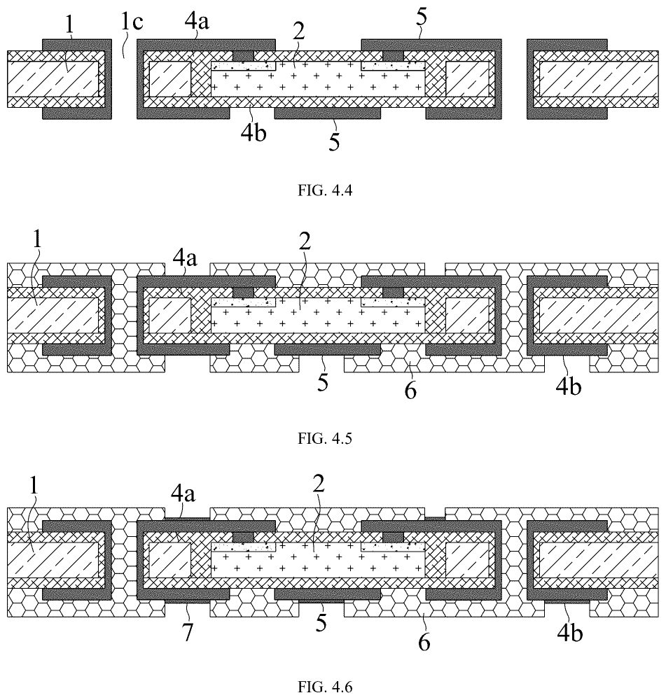

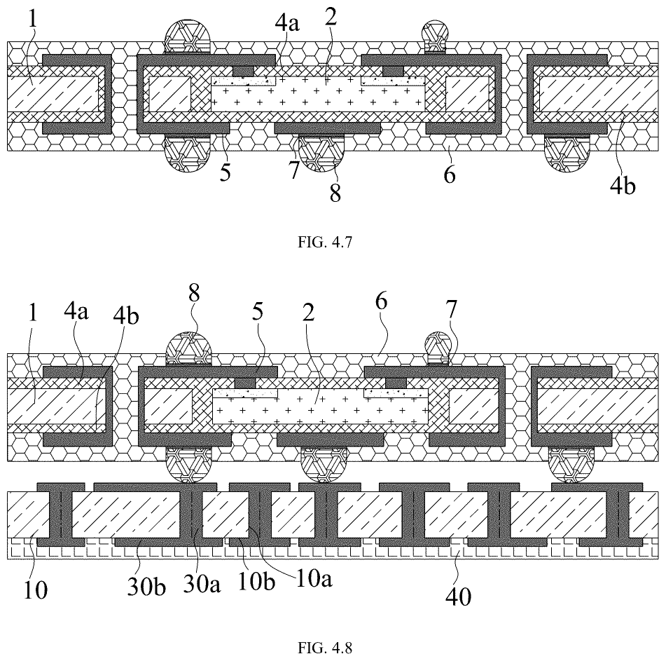

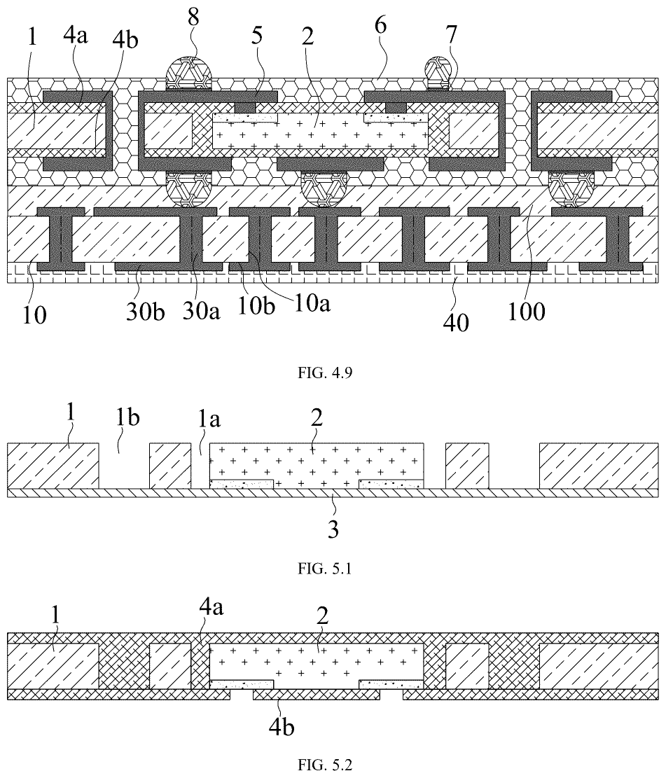

1. A first glass substrate 1 is provided, and a number of through holes 1b and a number of embedded grooves 1a (in the form of through holes) with a design size larger than the size of a chip 2 are opened on the first glass substrate 1.
2. The lower surface (the first surface) of the first glass substrate 1 is attached onto a temporary adhesive film 3.
3. A number of chips 2 are provided, an I/O port (bump pillar) of a chip 2 of the chips 2 protrudes out of the surface of the chip 2, and the chip 2 is attached onto the temporary adhesive film 3 in an embedded groove 1a of the embedded grooves 1a with the front surface of the chip 2 facing upwards (that is, the I/O port faces up), as shown in FIG. 4.1.
4. A first dielectric layer 4a is pressed onto the upper surface (the second surface) of the first glass substrate 1, the gap between the chip 2 and the first glass substrate 1 and the first through hole 1b are filled with the first dielectric layer 4a, and the first dielectric layer 4a is thinned by grinding to expose the I/O port of the chip 2, as shown in FIG. 4.2.
5. The temporary adhesive film 3 on the first surface of the first glass substrate 1 is removed.
6. A second dielectric layer 4b is pressed onto the first surface of the first glass substrate 1 to obtain a chip package.
7. A second through hole 1c is opened by laser on the first dielectric layer 4a filled in the first through hole 1b and the corresponding second dielectric layer 4b, as shown in FIG. 4.3.
8. A seed layer is synchronously prepared by vacuum sputtering on the inner wall of the second through hole 1c, the side of the first dielectric layer 4a away from the first glass substrate 1 and the side of the second dielectric layer 4b away from the first glass substrate 1.
9. A photosensitive film is attached onto the seed layer on the first dielectric layer 4a and the seed layer on the second dielectric layer 4b, and exposure and development are carried out to form a patterned window with part of the seed layer exposed.
10. A first redistribution layer 5 is synchronously prepared by electroplating on the surface of the seed layer on the inner wall of the second through hole 1c and in the patterned window, as shown in FIG. 4.4.
11. The residual photosensitive film is removed to expose part of the seed layer, and the exposed seed layer is etched.
12. Green oil is brushed in the second through hole 1c prepared with the seed layer and the first redistribution layer 5, on the surface of the first dielectric layer 4a, on the surface of the second dielectric layer 4b and on the surface of the first redistribution layer 5, and exposure and development are carried out after the green oil is cured to form a solder mask 6 that exposes the pad region of the first redistribution layer 5, as shown in FIG. 4.5, where the first dielectric layer 4a and the second dielectric layer 4b form a dielectric layer.
13. Nickel-palladium-gold is melted in the pad region of the first redistribution layer 5 to obtain a nickel-palladium-gold layer 7, as in FIG. 4.6.
14. A metal bump 8 is implanted in the nickel-palladium-gold layer 7 to obtain an embedded chip fan-out packaging structure shown in FIG. 4.7.

### II. Preparation of a Glass Metallized Circuit Structure

The preparation method here is exactly the same as the preparation method in Embodiment 2, and the details will not be repeated here.

III. Stacking, Welding, Filling with PI, and Sintering
1. As shown in FIG. 4.8, the metal bump of the embedded chip fan-out packing structure is butt-joined and secured by welding to the redistribution layer of the glass metallized circuit structure.
2. The gap between the embedded chip fan-out packaging structure and the glass metallized circuit structure is filled with PI, and sintering is carried out on PI at 100° C. for 2 hours to obtain an all-glass stacked packaging structure shown in FIG. 4.9.

As shown in FIG. 4.9, the all-glass stacked packaging structure in Embodiment 4 includes an embedded chip fan-out packaging structure and a glass metallized circuit structure that are stacked vertically. The metal bump 8 of the embedded chip fan-out packaging structure is connected to the second redistribution layer 30b of the glass metallized circuit structure, and the gap between the embedded chip fan-out packaging structure and the glass metallized circuit structure is filled with a connection layer 100 formed by sintering PI.

As shown in FIG. 4.9, the embedded chip fan-out packaging structure includes a first glass substrate 1, a number of chips 2, a seed layer, a first redistribution layer 5, a solder mask 6, a nickel-palladium gold layer 7 and a metal bump 8.

A number of embedded grooves 1a and a number of first through holes 1b are opened on the first glass substrate 1.

A chip 2 is located in an embedded groove 1a, the gap between the chip 2 and the embedded groove 1a and the first through hole 1b are filled with a dielectric layer, the I/O port of the chip 2 is exposed from the dielectric layer, and a second through hole 1c is opened on the dielectric layer of the first through hole 1b.

The seed layer is located on the inner wall of the second through hole 1c and is electrically connected to the I/O port of the chip 2.

The first redistribution layer 5 is located above the seed layer.

The solder mask 6 is filled in the second through hole 1c and on the surfaces of the first redistribution layer 5 and the dielectric layer, and the pad region of the first redistribution layer 5 is exposed from the solder mask 6.

The nickel-palladium-gold layer 7 is located in the pad region of the first redistribution layer 5 and is electrically connected to the metal bump 8.

In an implementation, the dielectric layer includes a first dielectric layer 4a and a second dielectric layer 4b. The first dielectric layer 4a is filled in the gap between the chip 2 and the embedded groove 1a and the first through hole 1b. The second surface (the upper surface) of the first glass substrate 1 is covered with the first dielectric layer 4a, and the first surface (the lower surface) of the first glass substrate 1 is covered with the second dielectric layer 4b.

The seed layer is disposed on the surfaces of the first dielectric layer 4a and the second dielectric layer 4b.

The glass metallized circuit structure here is exactly the same as the glass metallized circuit structure in Embodiment 2, and the details will not be repeated here.

The second glass substrate 10 of the glass metallized circuit structure is further fixedly connected to the embedded chip fan-out packaging structure via the connection layer 100 formed by sintering PI.

### Embodiment 5

The method of preparing an all-glass stacked packaging structure in Embodiment 5 is described below.

### I. Preparation of an Embedded Chip Fan-Out Packaging Structure

The method of preparing the embedded chip fan-out packaging structure in Embodiment 5 is basically the same as the preparation method in Embodiment 4 (reference is made to the accompanying drawings of Embodiment 4, and the same components keep the same reference numerals). The differences are that in Embodiment 5, the I/O port (a ubm) of the chip 2 is flush with the surface of the chip 2, and the chip 2 is attached onto the temporary adhesive film 3 in the embedded groove 1a with the front surface of the chip 2 upwards (that is, the I/O port faces up); the first dielectric layer 4a is pressed onto the upper surface (the second surface) of the first glass substrate 1, and laser drilling is carried out on the first dielectric layer 4a by aligning the I/O port of the chip 2 to expose the I/O port of the chip 2; the temporary adhesive film 3 on the first surface of the first glass substrate 1 is removed; the second dielectric layer 4b is pressed onto the first surface of the first glass substrate 1 to obtain the chip package. The subsequent steps of Embodiment 5 are the same as to the steps of Embodiment 4. The embedded chip fan-out packaging structure prepared here is also basically the same as the embedded chip fan-out packaging structure prepared in Embodiment 4, and the details will not be repeated here.

### II. Preparation of a Glass Metallized Circuit Structure

The preparation method here is exactly the same as the preparation method in Embodiment 2, and the details will not be repeated here.

III. Stacking, Welding, Filling with Na₂O·2SiO₂, and Sintering
1. The metal bump 8 of the embedded chip fan-out packing structure is butt-joined and secured by welding to the second redistribution layer 30b of the glass metallized circuit structure.
2. The gap between the embedded chip fan-out packaging structure and the glass metallized circuit structure is filled with Na₂O·2SiO₂, and sintering is carried out on Na₂O·2SiO₂ at 250° C. for 1.5 hours to obtain an all-glass stacked packaging structure.

The all-glass stacked packaging structure in Embodiment 5 includes an embedded chip fan-out packaging structure and a glass metallized circuit structure that are stacked vertically. The metal bump 8 of the embedded chip fan-out packaging structure is connected to the second redistribution layer 30b of the glass metallized circuit structure, and the gap between the embedded chip fan-out packaging structure and the glass metallized circuit structure is filled with a connection layer 100 formed by sintering Na₂O·2SiO₂.

The structure of the embedded chip fan-out packaging structure is basically the same as the embedded chip fan-out packaging structure prepared in Embodiment 4, and the details will not be repeated here.

The glass metallized circuit structure here is exactly the same as the glass metallized circuit structure in Embodiment 2, and the details will not be repeated here.

The second glass substrate 10 of the glass metallized circuit structure is connected to the embedded chip fan-out packaging structure via the connection layer 100 formed by sintering Na₂O·2SiO₂.

### Embodiment 6

### I. Preparation of an Embedded Chip Fan-Out Packaging Structure

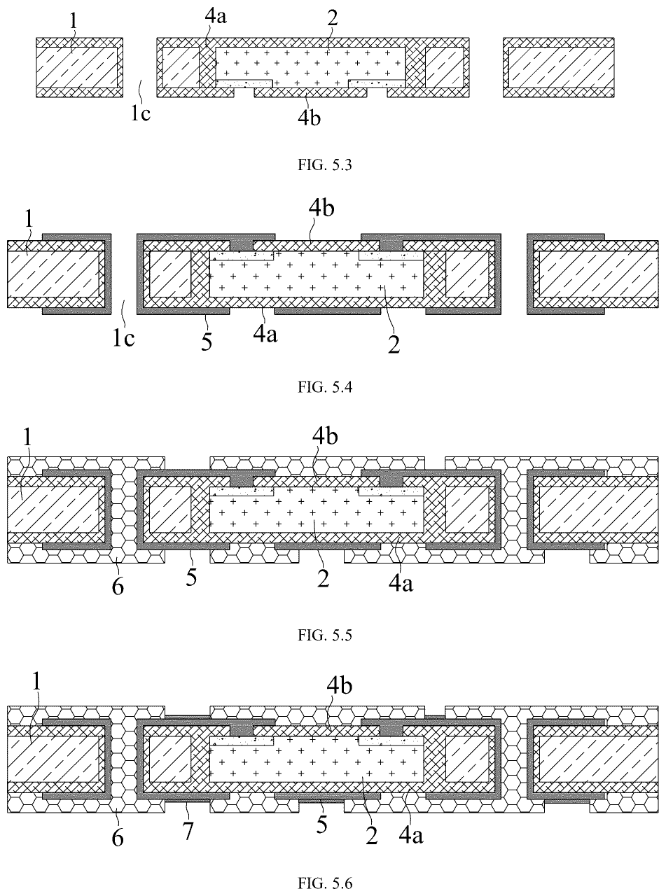

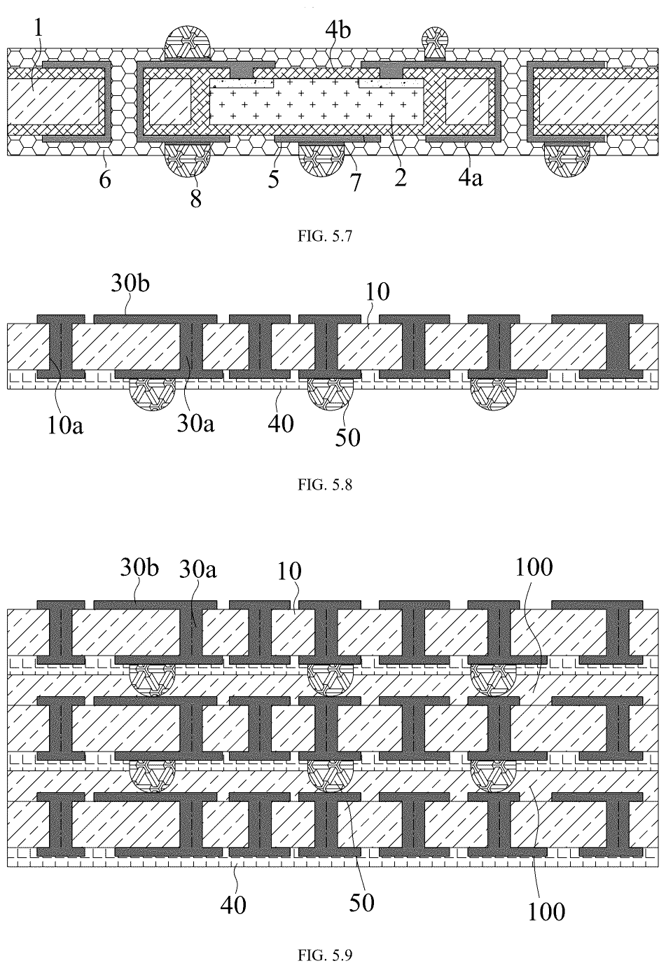

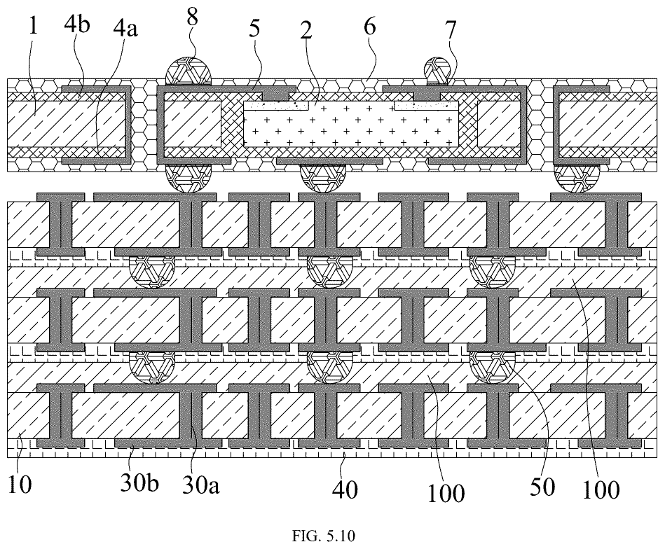

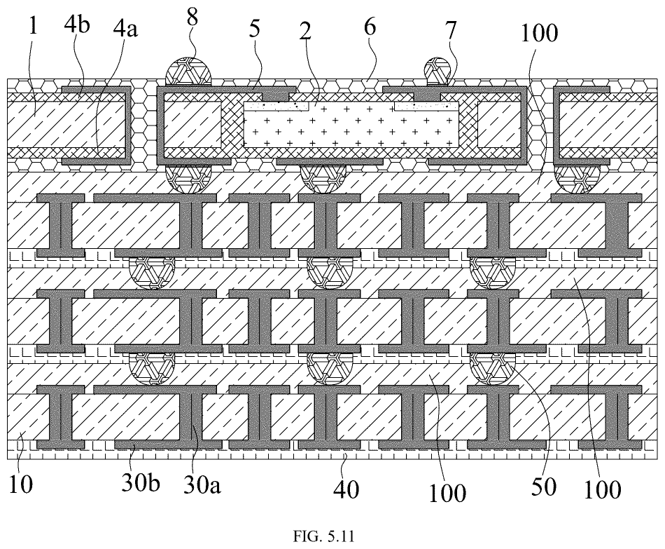

The method of preparing the embedded chip fan-out packaging structure in Embodiment 6 (FIG. 5.1 to 5.7) is basically the same as the preparation method in Embodiment 4. The differences are that in Embodiment 6, the I/O port (a ubm) of the chip 2 is flush with the surface of the chip 2, and the chip 2 is attached onto the temporary adhesive film 3 in the embedded groove 1a with the front surface of the chip facing downwards (that is, the I/O port faces up); the first dielectric layer 4a is pressed onto the upper surface (the second surface) of the first glass substrate 1 and is filled in the gap between the chip 2 and the first glass substrate 1 and the first through hole 1b; the temporary adhesive film 3 on the first surface of the first glass substrate 1 is removed; the second dielectric layer 4b is pressed onto the first surface of the first glass substrate 1; laser drilling is carried out on the second dielectric layer 4b to expose the I/O port of the chip 2 to obtain a chip package. The subsequent steps here are exactly the same as to the steps of Embodiment 4. The embedded chip fan-out packaging structure prepared here is also basically the same as the embedded chip fan-out packaging structure prepared in Embodiment 4, and the details will not be repeated here.

### II. Preparation of a Glass Metallized Circuit Structure

The glass metallized circuit structure in Embodiment 6 is formed by connecting one layer of first substrate structure and two layers of second substrate structures, and the preparation method specifically includes steps S10 to S90.

In S10, a second glass substrate 10 is provided, and laser modification is carried out on a portion of the second glass substrate 10 (which is the same as Embodiment 2).

In S20, the second glass substrate 10 is etched to form a through hole 10a in a laser-modified region.

In S30, a seed layer is prepared on the inner wall of the through hole 10a and both surfaces of the second glass substrate 10.

In S40, a photosensitive film 20 is separately pressed onto the seed layer on the both surfaces of the second glass substrate 10, and exposure and development are carried out to form a patterned window.

In S50, a second redistribution layer 30b is prepared in the patterned window, and a copper pillar 30a connected to the second redistribution layer 30b is filled in the through hole.

In S60, the residual photosensitive film 20 is removed, and flash etching is carried out on the exposed seed layer.

In S70, green oil is brushed on one side of the second glass substrate 10 and the surface of the second redistribution layer 30b corresponding to the one side of the second glass substrate 10, and a solder mask 40 covering the one side of the second glass substrate 10 and the corresponding second redistribution layer 30b is formed after the green oil is cured. Three first substrate structures (referring to FIG. 2.5) are prepared according to the steps described above.

In S80, two first substrate structures are provided, hole opening is carried out on the solder mask 40 of each first substrate structure to expose a pad region of the second redistribution layer 30b of each first substrate structure, and a metal bump 50 is implanted in the pad region to obtain two second substrate structures serving as an intermediate, as shown in FIG. 5.8.

In S90, the metal bump 50 of one second substrate structure of the two second substrate structure is coated with a nano-silver paste and is butt-joined and secured by sintering to the exposed second redistribution layer 30b of the first substrate structure; the metal bump 50 of the one second substrate structure is coated with the nano-sliver paste and is butt-joined and secured by sintering to the exposed second redistribution layer 30b of the other second substrate structure; Na₂O·2SiO₂ (the connecting material) is filled between the first substrate structure and the one second substrate structure and between two adjacent second substrate structures, and sintering is carried out on Na₂O·2SiO₂ (the connecting material) at 280° C. for 1 hour to obtain the glass metallized circuit structure (FIG. 5.9).

III. Stacking, Welding, Filling with Na₂O·3.5SiO₂, and Sintering
1. As shown in FIG. 5.10, the metal bump 8 of the embedded chip fan-out packing structure is butt-joined and secured by welding to the second redistribution layer 30b of the glass metallized circuit structure.
2. The gap between the embedded chip fan-out packaging structure and the glass metallized circuit structure is filled with Na₂O·3.5SiO₂, and sintering is carried out on Na₂O·3.5SiO₂ at 280° C. for 1 hour to obtain an all-glass stacked packaging structure shown in FIG. 5.11.

The all-glass stacked packaging structure in Embodiment 2 includes an embedded chip fan-out packaging structure and a glass metallized circuit structure that are stacked vertically. The metal bump 8 of the embedded chip fan-out packaging structure is connected to the second redistribution layer 30b of the glass metallized circuit structure, and the gap between the embedded chip fan-out packaging structure and the glass metallized circuit structure is filled with a connection layer 100 formed by sintering Na₂O·3.5SiO_{2.}

The structure of the embedded chip fan-out packaging structure is basically the same as the embedded chip fan-out packaging structure prepared in Embodiment 4, and the details will not be repeated here.

As shown in FIG. 5.11, the glass substrate metallized structure in Embodiment 6 includes one first substrate structure and two second substrate structures.

The first substrate structure includes a second glass substrate 10, a conductive pillar, a circuit layer and a solder mask 40.

A through hole 10a is opened on the second glass substrate 10.

The conductive pillar includes a first seed layer and a copper pillar 30a. The first seed layer covers the inner wall of the through hole 10a. The copper pillar 30a is filled in the through hole 10a covered with the first seed layer on the inner wall.

The circuit layer includes a second seed layer and a second redistribution layer 30b. The second seed layer is located on both surfaces of the second glass substrate 10 and is electrically connected to the first seed layer. The second redistribution layer 30b is located on the second seed layer on both surfaces of the second glass substrate 10 and the copper pillar 30a and is electrically connected to the copper pillar 30a.

The first seed layer and the second seed layer form a seed layer and are integrally formed by vacuum sputtering. The copper pillar 30a and the second redistribution layer 30b are integrally deposited by electroplating.

The solder mask 40 covers one side of the second glass substrate 10 and the second redistribution layer 30b on the one side.

The second substrate structure is basically the same as the first substrate structure, and the difference is that in the second substrate structure, the solder mask 40 is provided with a hole structure for exposing the pad region of the second redistribution layer 30b and a metal bump 50 secured by welding to the pad region of the second redistribution layer 30b.

The metal bump 50 of the second substrate structure is electrically connected to the second redistribution layer 30b of the first substrate structure via a connection portion formed by sintering the nanometal paste.

In an embodiment, the connection layer 100 formed by sintering Na₂O·3.5SiO₂ is filled between two adjacent second substrate structures of the glass substrate metallized structure and between the first substrate structure and the second substrate structure.

The second glass substrate 10 of the glass metallized circuit structure is connected to the embedded chip fan-out packaging structure via the connection layer 100 formed by sintering Na₂O·3.5SiO₂.

1. A method of preparing an all-glass stacked packaging structure, comprising following steps:
S1: providing an embedded chip fan-out packaging structure provided with a glass substrate and a glass metallized circuit structure provided with a glass substrate, and butt-joining and securing by welding a metal bump of the embedded chip fan-out packaging structure to an exposed second redistribution layer of the glass metallized circuit structure; and
S2: filling a gap between the embedded chip fan-out packaging structure and the glass metallized circuit structure with a connecting material, and carrying out sintering on the connecting material at 160-300° C. for 0.5-4 h to obtain the all-glass stacked packaging structure, wherein the connecting material is a solid inorganic silicate; wherein the inorganic silicate is Na₂O·nSiO₂, wherein n=0.1-5.

2. (canceled)

3. The method of preparing an all-glass stacked packaging structure according to claim 1, wherein in step S1, a method of preparing the embedded chip fan-out packaging structure comprises following steps:
S10: providing a first glass substrate, and opening on the first glass substrate a number of embedded grooves with a design size larger than a size of a chip;
S20: attaching a first surface of the first glass substrate onto a temporary adhesive film, and attaching the chip into an embedded groove of the embedded grooves;
S30: separately preparing a dielectric layer on the first surface of the first glass substrate and a second surface of the first glass substrate, and processing the dielectric layer to expose an I/O port of a chip to obtain a chip package;
S40: carrying out hole opening on the chip package to form a number of through holes penetrating through the chip package; and
S50: electrically leading the I/O port of the chip via a through hole of the through holes out of both surfaces of the chip package synchronously to obtain the embedded chip fan-out packaging structure.

4. The method of preparing an all-glass stacked packaging structure according to claim 3, wherein in step S20, the I/O port of the chip protrudes out of a surface of the chip, and after the chip is attached into the embedded groove with a front surface of the chip facing upwards, step S30 specifically comprises following steps:
S30a: preparing a first dielectric layer on the second surface of the first glass substrate;
S30b: thinning, by grinding, the first dielectric layer to expose the I/O port of the chip;
S30c: removing the temporary adhesive film; and
S30d: preparing a second dielectric layer on the first surface of the first glass substrate to obtain the chip package.

5. The method of preparing an all-glass stacked packaging structure according to claim 3, wherein in step S20, the I/O port of the chip is flush with a surface of the chip, and after the chip is attached into the embedded groove with a front surface of the chip facing upwards, step S30 specifically comprises following steps:
S30a: preparing a first dielectric layer on the second surface of the first glass substrate;
S30b: carrying out laser drilling on the first dielectric layer to expose the I/O port of the chip;
S30c: removing the temporary adhesive film; and
S30d: preparing a second dielectric layer on the first surface of the first glass substrate to obtain the chip package.

6. The method of preparing an all-glass stacked packaging structure according to claim 3, wherein in step S20, the I/O port of the chip is flush with a surface of the chip, and when the chip is attached into the embedded groove with a front surface of the chip facing downwards, step S30 specifically comprises following steps:
S30a: preparing a first dielectric layer on the second surface of the first glass substrate;
S30b: removing the temporary adhesive film;
S30c: preparing a second dielectric layer on the first surface of the first glass substrate; and
S30d: carrying out laser drilling on the second dielectric layer to expose the I/O port of the chip to obtain the chip package.

7. The method of preparing an all-glass stacked packaging structure according to claim 3, wherein step S50 comprises following steps:
S50a: preparing a seed layer on a surface of the chip package and an inner wall of the through hole;
S50b: attaching a photosensitive film onto the seed layer on the surface of the chip package, and carrying out exposure and development to form a patterned window;
S50c: preparing a first redistribution layer in the patterned window and on an inner wall of the through hole;
S50d: removing a residual photosensitive film and etching away an exposed seed layer;
S50e: preparing a solder mask in the through hole and on both surfaces of the chip package prepared with the first redistribution layer, and exposing a pad region of the first redistribution layer; and
S50f: preparing a nickel-palladium-gold layer in the pad region of the first redistribution layer, and implanting a metal bump in the nickel-palladium-gold layer to obtain the embedded chip fan-out packaging structure.

8. The method of preparing an all-glass stacked packaging structure according to claim 1, wherein in step S1, a method of preparing the embedded chip fan-out packaging structure comprises following steps:
S10: providing a first glass substrate, and opening on the first glass substrate a number of first through holes and a number of embedded grooves with a design size larger than a size of a chip;
S20: attaching a first surface of the first glass substrate onto a temporary adhesive film, and attaching the chip into an embedded groove of the embedded grooves;
S30: preparing a dielectric layer on each of the first surface of the first glass substrate and a second surface of the first glass substrate, filling a first through hole of the first through holes and a gap between the chip and the first glass substrate with the dielectric layer, and processing the dielectric layer to expose an I/O port of a chip to obtain a chip package;
S40: opening a second through hole on the dielectric layer filled in the first through hole; and
S50: electrically leading the I/O port of the chip via the second through hole out of both surfaces of the chip package synchronously to obtain the embedded chip fan-out packaging structure.

9. The method of preparing an all-glass stacked packaging structure according to claim 8, wherein in step S20, the I/O port of the chip protrudes out of a surface of the chip, and after the chip is attached into the embedded groove with a front surface of the chip facing upwards, step S30 specifically comprises following steps:
S30a: preparing a first dielectric layer on the second surface of the first glass substrate;
S30b: thinning, by grinding, the first dielectric layer to expose the I/O port of the chip;
S30c: removing the temporary adhesive film; and
S30d: preparing a second dielectric layer on the first surface of the first glass substrate to obtain the chip package.

10. The method of preparing an all-glass stacked packaging structure according to claim 8, wherein in step S20, the I/O port of the chip is flush with a surface of the chip, and after the chip is attached into the embedded groove with a front surface of the chip facing upwards, step S30 specifically comprises following steps:
S30a: preparing a first dielectric layer on the second surface of the first glass substrate;
S30b: carrying out laser drilling on the first dielectric layer to expose the I/O port of the chip;
S30c: removing the temporary adhesive film; and
S30d: preparing a second dielectric layer on the first surface of the first glass substrate to obtain the chip package.

11. The method of preparing an all-glass stacked packaging structure according to claim 8, wherein in step S20, the I/O port of the chip is flush with a surface of the chip, and when the chip is attached into the embedded groove with a front surface of the chip downwards, step S30 specifically comprises following steps:
S30a: preparing a first dielectric layer on the second surface of the first glass substrate;
S30b: removing the temporary adhesive film;
S30c: preparing a second dielectric layer on the first surface of the first glass substrate; and
S30d: carrying out laser drilling on the second dielectric layer to expose the I/O port of the chip to obtain the chip package.

12. The method of preparing an all-glass stacked packaging structure according to claim 8, wherein step S50 specifically comprises following steps:
S50a: preparing a seed layer on a surface of the chip package and an inner wall of the second through hole;
S50b: attaching a photosensitive film onto the seed layer on the surface of the chip package, and carrying out exposure and development to form a patterned window;
S50c: preparing a first redistribution layer in the patterned window and on the inner wall of the second through hole;
S50d: removing a residual photosensitive film and etching away an exposed seed layer;
S50e: preparing a solder mask in the second through hole and on both surfaces of the chip package prepared with the first redistribution layer, and exposing a pad region of the first redistribution layer; and
S50f: preparing a nickel-palladium-gold layer in the pad region of the first redistribution layer, and implanting a metal bump in the nickel-palladium-gold layer to obtain the embedded chip fan-out packaging structure.

13. The method of preparing an all-glass stacked packaging structure according to claim 8, wherein in step S40, the second through hole is opened by laser on the dielectric layer filled in the first through hole.

14. The method of preparing an all-glass stacked packaging structure according to claim 2, wherein a method of preparing the glass metallized circuit structure comprises following steps:
S100: providing a second glass substrate, and carrying out laser modification on a portion of the second glass substrate;
S200: pressing a photosensitive film onto both surfaces of the second glass substrate, carrying out exposure and development to form a first patterned window, and exposing a laser-modified region of the second glass substrate from the first patterned window;
S300: etching the second glass substrate to form a through hole in the laser-modified region and an embedded circuit groove in a non-laser-modified region at the first patterned window;
S400: removing a residual photosensitive film, and preparing a seed layer on a surface of the embedded circuit groove and an inner wall of the through hole;
S500: pressing a photosensitive film onto a surface of the second glass substrate and the seed layer on the surface of the embedded circuit groove, and carrying out exposure and development on the photosensitive film to form a second patterned window;
S600: preparing a conductive pillar in the through hole, and preparing in the second patterned window a second redistribution layer electrically connected to the conductive pillar, wherein a surface of the second redistribution layer is flush with the surface of the second glass substrate;
S700: removing a residual photosensitive film, and carrying out flash etching on an exposed seed layer; and
S800: preparing a solder mask on one side of the second glass substrate and a surface of a second redistribution layer corresponding to the one side of the second glass substrate to cover the second glass substrate and the corresponding second redistribution layer to obtain the glass metallized circuit structure.

15. The method of preparing an all-glass stacked packaging structure according to claim 2, wherein a method of preparing the glass metallized circuit structure comprises following steps:
S100: providing a second glass substrate, and carrying out laser modification on a portion of the second glass substrate;
S200: pressing a photosensitive film onto both surfaces of the second glass substrate, carrying out exposure and development to form a first patterned window, and exposing a laser-modified region of the second glass substrate from the first patterned window;
S300: etching the second glass substrate to form a through hole in the laser-modified region and an embedded circuit groove in a non-laser-modified region at the first patterned window;
S400: removing a residual photosensitive film, and preparing a seed layer on a surface of the embedded circuit groove and an inner wall of the through hole;
S500: pressing a photosensitive film onto a surface of the second glass substrate and the seed layer on the surface of the embedded circuit groove, and carrying out exposure and development on the photosensitive film to form a second patterned window;
S600: preparing a conductive pillar in the through hole, and preparing in the second patterned window a second redistribution layer electrically connected to the conductive pillar, wherein a surface of the second redistribution layer is flush with the surface of the second glass substrate;
S700: removing a residual photosensitive film, and carrying out flash etching on an exposed seed layer; preparing a solder mask on one side of the second glass substrate and a surface of a second redistribution layer corresponding to the one side of the second glass substrate to cover the second glass substrate and the second redistribution layer;
S800: preparing (m+1) first substrate structures according to steps S100-S700, wherein m is a positive integer, carrying out hole opening on a solder mask of each of m first substrate structures to expose a pad region of a second redistribution layer of each of the m first substrate structures, and implanting a metal bump in the pad region to obtain a second substrate structure serving as an intermediate; and
S900: coating a metal bump of one second substrate structure with a nanometal paste, and butt-joining and securing by sintering the metal bump of the one second substrate structure to an exposed second redistribution layer of a first substrate structure; then, coating a metal bump of another second substrate structure with the nanometal paste, and butt-joining and securing by sintering the metal bump of the another second substrate structure to an exposed second redistribution layer of the one second substrate structure; securing all the second substrate structures in a same manner; finally, filling the connecting material between the first substrate structure and the second substrate structure and between each of two adjacent second substrate structures, and carrying out sintering on the connecting material to obtain the glass metallized circuit structure.

16. The method of preparing an all-glass stacked packaging structure according to claim 14, wherein in step S300, an etching rate ratio of the laser-modified region to the non-laser-modified region of the second glass substrate is 20:1.

17. The method of preparing an all-glass stacked packaging structure according to claim 1, wherein a method of preparing the glass metallized circuit structure comprises following steps:
S100: providing a second glass substrate, and carrying out laser modification on a portion of the second glass substrate;
S200: etching the second glass substrate to form a through hole in a laser-modified region;
S300: preparing a seed layer on an inner wall of the through hole and both surfaces of the second glass substrate;
S400: separately pressing a photosensitive film onto the seed layer on the both surfaces of the second glass substrate, and carrying out exposure and development to form a patterned window;
S500: preparing a second redistribution layer in the patterned window, and filling in the through hole a copper pillar connected to the second redistribution layer;
S600: removing a residual photosensitive film, and carrying out flash etching on an exposed seed layer; and
S700: preparing a solder mask on one side of the second glass substrate and a surface of a second redistribution layer corresponding to the one side of the second glass substrate to cover the second glass substrate and the second redistribution layer to obtain the glass metallized circuit structure.

18. The method of preparing an all-glass stacked packaging structure according to claim 1, wherein a method of preparing the glass metallized circuit structure comprises following steps:
S100: providing a second glass substrate, and carrying out laser modification on a portion of the second glass substrate;
S200: etching the second glass substrate to form a through hole in a laser-modified region;
S300: preparing a seed layer on an inner wall of the through hole and both surfaces of the second glass substrate;
S400: separately pressing a photosensitive film onto the seed layer on the both surfaces of the second glass substrate, and carrying out exposure and development to form a patterned window;
S500: preparing a second redistribution layer in the patterned window, and filling in the through hole a copper pillar connected to the second redistribution layer;
S600: removing a residual photosensitive film, and carrying out flash etching on an exposed seed layer;
S700: preparing a solder mask on one side of the second glass substrate and a surface of a second redistribution layer corresponding to the one side of the second glass substrate to cover the one side of the second glass substrate and the second redistribution layer;
S800: preparing (m+1) first substrate structures according to steps S100-S700, wherein m is a positive integer, carrying out hole opening on a solder mask of each of m first substrate structures to expose a pad region of a second redistribution layer of each of the m first substrate structures, and implanting a metal bump in the pad region to obtain a second substrate structure serving as an intermediate; and
S900: coating a metal bump of one second substrate structure with a nanometal paste, and butt-joining and securing by sintering the metal bump of the one second substrate structure to an exposed second redistribution layer of a first substrate structure; then, coating a metal bump of another second substrate structure with the nanometal paste, and butt-joining and securing by sintering the metal bump of the another second substrate structure to an exposed second redistribution layer of the one second substrate structure; securing all second substrate structures in a same manner; finally, filling the connecting material between the first substrate structure and the second substrate structure and between each of two adjacent second substrate structures, and carrying out sintering on the connecting material to obtain the glass metallized circuit structure.

19. An all-glass stacked packaging structure prepared by using the preparation method according to claim 1, comprising an embedded chip fan-out packaging structure and a glass metallized circuit structure that are stacked vertically, wherein a metal bump of the embedded chip fan-out packaging structure is connected to an exposed second redistribution layer of the glass metallized circuit structure, and a gap between the embedded chip fan-out packaging structure and the glass metallized circuit structure is filled with a connection layer formed by sintering a connecting material.

20. The method of preparing an all-glass stacked packaging structure according to claim 15, wherein in step S300, an etching rate ratio of the laser-modified region to the non-laser-modified region of the second glass substrate is 20:1.
